(19) United States
(12) Patent Application Publication
(10) Pub. No.: US 2024/0357906 A1
(43) Pub. Date: Oct. 24, 2024

(54) LIGHT-EMITTING ELEMENT AND LIGHT-EMITTING DEVICE

(71) Applicant: SHARP KABUSHIKI KAISHA, Sakai City, Osaka (JP)

(72) Inventors: YASUSHI ASAOKA, Sakai City, Osaka (JP); JUN SAKUMA, Sakai City, Osaka (JP)

(21) Appl. No.: 18/685,289

(22) PCT Filed: Oct. 13, 2021
(86) PCT No.: PCT/JP2021/037950

§ 371 Date: Feb. 21, 2024

(51) Int. Cl. H10K 59/80

(52) U.S. Cl. CPC H10K 59/878; H10K 59/8791

(57) ABSTRACT

A light-emitting element includes a light absorption layer for transmitting at least part of light that is visible light of a first color emitted by a light-emitting layer in a functional layer and absorbing at least part of visible light other than the light. The light absorption layer is disposed adjacent to both a reflective layer and a first electrode and covers the entire reflective layer in a light-emitting region.

### TECHNICAL FIELD

The present disclosure relates to light-emitting elements and light-emitting devices, each of which includes a light absorption layer.

### BACKGROUND ART

Some conventionally known light-emitting devices such as OLED (organic light-emitting diode) display devices and QLED (quantum-dot light-emitting diode) display devices, as well as light-emitting elements used in these light-emitting devices, include a reflective structure for the purpose of improving light-extraction efficiency. Patent Literature 1 to 7 discloses examples of such light-emitting devices and light-emitting elements.

### CITATION LIST

### Patent Literature

Patent Literature 1: Japanese Unexamined Patent Application Publication No. 2019-102449

Patent Literature 2: Japanese Unexamined Patent Application Publication No. 2004-192977

Patent Literature 3: Japanese Unexamined Patent Application Publication No. 2009-117500

Patent Literature 4: Japanese Unexamined Patent Application Publication No. 2007-280677

Patent Literature 5: Japanese Unexamined Patent Application Publication No. 2017-004746

Patent Literature 6: Japanese Unexamined Patent Application Publication No. 2006-276089

Patent Literature 7: PCT International Application Publication No. WO2017/043245

### SUMMARY OF INVENTION

### Technical Problem

In conventional art, the external light incident to the light-emitting device or element is reflected and/or scattered by the reflective structure for discharge from the light-emitting device or element to the outside. Due to this external light discharged from the light-emitting device or element, conventional art has a problem that the light-emitting device or element discharges light with low contrast.

The present disclosure, in an aspect thereof, has been made in view of this problem and has an object to provide a light-emitting element and a light-emitting device, both of which can discharge light with high contrast.

### Solution to Problem

The present disclosure, in one aspect thereof, is directed to a light-emitting element including: a reflective layer; a light absorption layer; a first electrode that is transparent to visible light; a functional layer including at least a light-emitting layer configured to emit visible light of a first color; and a second electrode that is transparent to visible light, all of which are provided in a stated order, wherein the light absorption layer transmits at least part of the visible light of the first color and absorbs at least part of visible light other than the visible light of the first color, is disposed adjacent to both the reflective layer and the first electrode, and covers the entire reflective layer in a light-emitting region of the light-emitting element.

The present disclosure, in one aspect thereof, is directed to a light-emitting device including a plurality of the light-emitting elements of an aspect of the present disclosure.

### Advantageous Effects of Invention

The present disclosure, in an aspect thereof, provides a light-emitting element and a light-emitting device, both of which can discharge light with high contrast.

### BRIEF DESCRIPTION OF DRAWINGS

FIG. 1 is a schematic cross-sectional view and plan view of a structure of a light-emitting element in accordance with Embodiment 1.

FIG. 2 is a pair of diagrams, arranged on top of the other, that represent the visible-light emission spectra of light-emitting layers prepared using different light-emitting materials.

FIG. 3 is a schematic cross-sectional view of a structure of a light-emitting element in accordance with a variation example of Embodiment 1.

FIG. 4 is a schematic cross-sectional view of a structure of a light-emitting element in accordance with Embodiment 2.

FIG. 5 is a schematic cross-sectional view of a structure of another light-emitting element in accordance with Embodiment 2.

FIG. 6 is a set of plan views, arranged next to each other, of five examples of depressions formed in an insulating layer.

FIG. 7 is a schematic cross-sectional view of a structure of a light-emitting element in accordance with Embodiment 4.

FIG. 8 is a schematic cross-sectional view of a structure of another light-emitting element in accordance with Embodiment 4.

FIG. 9 is a schematic cross-sectional view of a structure of a light-emitting element in accordance with a variation example of Embodiment 4.

FIG. 10 is a schematic cross-sectional view of a structure of a light-emitting element in accordance with Embodiment 5.

FIG. 11 is a schematic cross-sectional view of a structure of a light-emitting element in accordance with Embodiment 6.

FIG. 12 is a schematic cross-sectional view of a structure of another light-emitting element in accordance with Embodiment 6.

FIG. 13 is a schematic cross-sectional view of a structure of yet another light-emitting element in accordance with Embodiment 6.

FIG. 14 is a schematic cross-sectional view of a structure of still another light-emitting element in accordance with Embodiment 6.

FIG. 15 is a schematic block diagram of a structure of a light-emitting device in accordance with Embodiment 7.

FIG. 16 is a diagram showing a maximum transmission wavelength and a maximum absorption wavelength, both in the visible light wavelength range, of a first light absorption layer, a maximum transmission wavelength and a maximum absorption wavelength, both in the visible light wavelength range, of a second light absorption layer, and a maximum transmission wavelength and a maximum absorption wavelength, both in the visible light wavelength range, of a third light absorption layer, all of the light absorption layers being provided in a light-emitting device in accordance with Embodiment 7.

FIG. 17 is a schematic block diagram of a structure of a light-emitting device in accordance with Embodiment 8.

FIG. 18 is a diagram showing a maximum transmission wavelength and a maximum absorption wavelength, both in the visible light wavelength range, of a light absorption layer as a first light absorption layer and a third light absorption layer and a maximum transmission wavelength and a maximum absorption wavelength, both in the visible light wavelength range, of a light absorption layer as a second light absorption layer, all of the light absorption layers being provided in a light-emitting device in accordance with Embodiment 8.

FIG. 19 is a diagram showing a maximum transmission wavelength and a maximum absorption wavelength, both in the visible light wavelength range, of a light absorption layer as a first light absorption layer and a third light absorption layer and a maximum transmission wavelength and a maximum absorption wavelength, both in the visible light wavelength range, of a light absorption layer as a second light absorption layer, all of the light absorption layers being provided in a light-emitting device in accordance with Variation Example 1 of Embodiment 8.

### DESCRIPTION OF EMBODIMENTS

The following will describe embodiments of the present disclosure. Note that for convenience of description, those members which have the same function as previously described members will be indicated by the same reference numerals, and description thereof may not be repeated. Additionally, the angles described below, such as the angle of an inclined face, the reflection and refraction angles of external light, and the reflection and refraction angles of the light emitted by a light-emitting layer, are merely shown for convenience of illustration in the cross-sectional views and may differ from actual angles.

### Embodiment 1

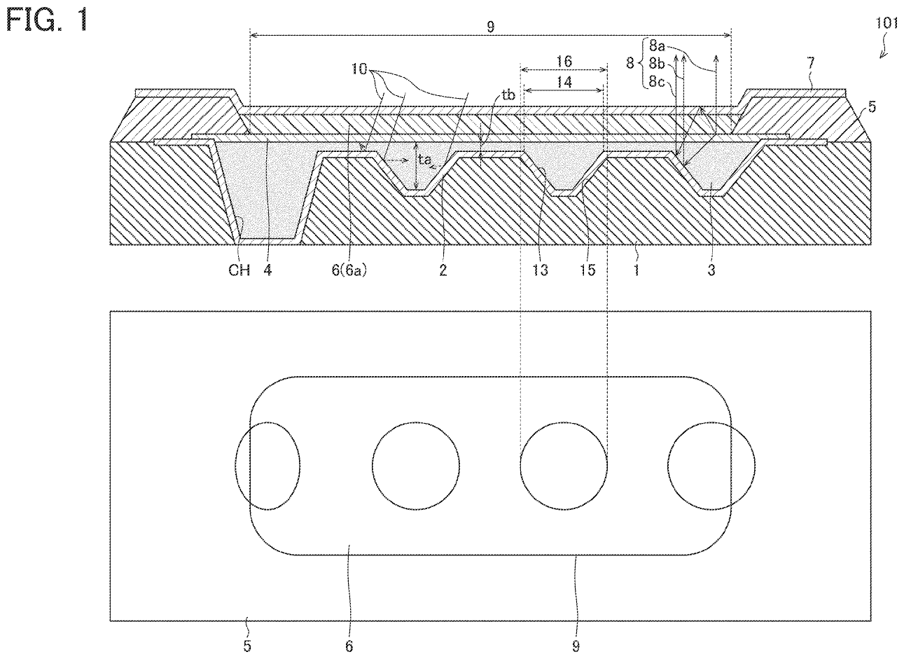

FIG. 1 is a schematic cross-sectional view and plan view of a structure of a light-emitting element 101 in accordance with the present embodiment. Referring to FIG. 1, the light-emitting element 101 includes an insulating layer 1 (first insulating layer), a reflective layer 2, a light absorption layer 3, a first electrode 4, an edge cover 5, a functional layer 6, and a second electrode 7. Note that the second electrode 7 is omitted in the plan view of FIG. 1 for convenience of illustration.

Note that throughout the following description, expressions like “component A underlies/is below component B” indicate that component A is formed in an earlier process or step than component B, and expressions like “component A overlies/is on/is above component B” indicate that component A is formed in a later process or step than component B. In addition, expressions like “component A is in the same layer as component B” indicate that components A and B are formed in a single process or step (film formation step). In addition, throughout the present specification, the direction from the insulating layer 1 toward the second electrode 7 is referred to as “upward,” and the opposite direction from the upward direction is referred to as “downward.” Specifically, the underlying layer side (or the lower side) of a given component refers to a component(s) that is/are closer to the substrate than the component is close to the substrate.

The light-emitting element 101 includes: the insulating layer 1; the reflective layer 2; the light absorption layer 3; the first electrode 4; the edge cover 5 and the functional layer 6; and the second electrode 7, all of which are provided in this order when viewed from a substrate (not shown) that is provided below the insulating layer 1. In the present disclosure, the layers between the first electrode 4 and the second electrode 7 are collectively referred to as the functional layer 6. The functional layer 6 includes at least a light-emitting layer 6a.

The substrate is a support body for supporting the insulating layer 1, the reflective layer 2, the light absorption layer 3, the first electrode 4, the edge cover 5, the functional layer 6, and the second electrode 7.

The light-emitting element 101 may be used, for example, as a light source in a display device, a lighting device, or a like light-emitting device (electronic apparatus). When the light-emitting element 101 is, for example, a part of such a light-emitting device, the substrate is a substrate for a light-emitting device including the light-emitting element 101 such as an array substrate carrying a plurality of thin film transistors formed thereon.

Therefore, the light-emitting element 101 per se may or may not include the substrate. In other words, the light-emitting element 101 may be called as such with or without the substrate.

The insulating layer 1 is formed across the substrate to cover the entire surface of the substrate. In the present embodiment, the insulating layer 1 and the reflective layer 2 form a reflective structural body that has projections and depressions in the surface thereof. Note that the surface of the reflective layer 2 forms the reflective surface of the reflective structural body. The reflective layer 2 reflects light 8 (EL light) emitted by the light-emitting layer 6a in the functional layer 6 and also reflects external light 10. Note that the light 8 is monochromatic (first color) visible light.

Referring to FIG. 1, the surface of the insulating layer 1 has a plurality of depressions 16 (e.g., four depressions 16) each with an inclined inner wall face 15 (inclined face portion) in a light-emitting region 9 of the light-emitting element 101. The reflective layer 2 is provided as a thin layer on the insulating layer 1 and is, in FIG. 1, disposed spreading on the surface of the insulating layer 1 at least in the light-emitting region 9 so as to cover the entire inner wall faces 15 of the depressions 16 in the insulating layer 1.

Note that in the present disclosure, a “light-emitting region” of a light-emitting element refers to a region where the light-emitting element emits light to the outside. In other words, in the present disclosure, a “light-emitting region” of a light-emitting element refers to a light-extracting region through which the light emitted by the light-emitting layer can be extracted to the outside in a plan view. The light-emitting layer emits light in a region sandwiched by the first electrode and the second electrode. Therefore, the region where the light-emitting layer overlaps the first electrode and the second electrode in a plan view is the light-emitting region of the light-emitting layer. However, the first electrode has an edge thereof covered by, for example, an electrically insulating edge cover that absorbs or blocks visible light to prevent the first electrode and the second electrode from being short-circuited due to a reduced thickness of the functional layer and/or a concentration of electric field at an end of the first electrode pattern. The light emitted by the light-emitting layer cannot be extracted to the outside through the region overlapping the edge cover in a plan view. In addition, as will be described in Embodiment 4 below, the reflection of ed the light emitted by the light-emitting layer can be extracted through regions of the light-emitting layer other than the light-emitting region, albeit at reduced light-extraction efficiency, if the regions are not covered by the edge cover in a plan view. Therefore, in the present disclosure, the region where the light-emitting element emits light to the outside is referred to as the light-emitting region of the light-emitting element, regardless of whether or not the region is a light-emitting region of the light-emitting layer (e.g., regardless of whether or not the region includes the first electrode therein). The light-emitting region of the light-emitting element will be referred to as the “light-emitting region 9” throughout the following description.

Therefore, in the present embodiment, the light-emitting region 9 refers to the region where the light-emitting element 101 emits light to the outside.

Note that when the light-emitting element in accordance with the present disclosure is used in a display device, the light-emitting region 9 is a pixel of the display device. The light-emitting region 9 is the region that is surrounded by the edge cover 5 and that doubles as a pixel-separating wall (in other words, an opening in the edge cover 5) and is a region of the light-emitting layer 6a that does not overlap the edge cover 5 in a plan view. Therefore, the light-emitting region 9 may alternatively be understood as referring to the pixel or the edge-covering opening. Note that the edge cover 5 and the material for the insulating layer 1 will be described later.

The surface of the reflective layer 2 has a plurality of depressions 14 (e.g., four depressions 14) each with an inclined inner wall face 13 (inclined face portion) in the light-emitting region 9.

This provision of the reflective layer 2 along the surface of the insulating layer 1 at least in the light-emitting region 9 where the insulating layer 1 has the depressions 16 each with the inclined inner wall face 15 facilitates the formation of the reflective layer 2 having the depressions 14 each with the inclined inner wall face 13.

In the present embodiment, the reflective layer 2 covers at least the entire inner wall faces 15 of the plurality of depressions 16 in the insulating layer 1 in the light-emitting region 9. Note that in the example shown in FIG. 1, the reflective layer 2 covers the entire inner wall faces 15 of the plurality of depressions 16 in the insulating layer 1. Therefore, the depression 14 is geometrically similar to the depression 16, and the inner wall face 13 is geometrically similar to the inclined inner wall face 15 of the depression 16.

This provision of the plurality of inclined inner wall faces 13 (in other words, inclined reflective surfaces) renders the resultant light-emitting element 101 capable of exhibiting further improved light-extraction efficiency in the front direction.

Note that as described above, FIG. 1 shows as an example a structure in which the insulating layer 1 has the plurality of depressions 16 in the light-emitting region 9 and the reflective layer 2 hence has the plurality of depressions 14 in the light-emitting region 9. However, the present embodiment is not limited to this example.

The reflective layer 2 needs only to have at least one depression 14 with an inclined inner wall face 13 in the light-emitting region 9. Therefore, the insulating layer 1 needs only to have one depression 16 with an inclined inner wall face 15 on the reflective layer 2 opposite the light absorption layer 3 in the light-emitting region 9.

This provision of the reflective layer 2 having at least one depression 14 with an inclined inner wall face 13 in the light-emitting region 9 enables prevention of waveguide loss and improvement of the light-extraction efficiency of the light-emitting element 101 in the front direction.

Note that one of the four depressions 16 that has the deepest bottom (the leftmost depression 16 in FIG. 1) additionally serves as a contact hole CH for electrically connecting the first electrode 4 to one of the TFT's (not shown) on the substrate.

Note that the material for the reflective layer 2 will be described later.

The reflective layer 2 in the light-emitting region 9 is covered by the light absorption layer 3. Meanwhile, the portion of the reflective layer 2 that is out of the light-emitting region 9 (i.e., the portion outside the light-emitting region 9) is directly or indirectly covered at least by the edge cover 5 (detailed later) and optionally also by the light absorption layer 3.

The light absorption layer 3 is disposed adjacent to both the reflective layer 2 and the first electrode between the reflective layer 2 and the first electrode 4.

The light absorption layer 3 absorbs light in a particular wavelength range and transmits light in a particular wavelength range. For example, the light absorption layer 3 transmits at least part of the visible light EL-emitted by the light-emitting layer 6a and absorbs at least part of visible light other than the EL-emission wavelengths produced by the light-emitting layer 6a. The light absorption layer 3 exhibits a high transmittance, for example, for emission wavelengths produced by the light-emitting layer 6a. Specifically, the light absorption layer 3 has a higher transmittance to light of a maximum light-emission luminance wavelength (e.g., peak-luminance wavelength for EL light emission) that is the wavelength at which the visible light of a color (first color) of the light EL-emitted at least by the light-emitting layer 6a reaches a maximum light-emission luminance, than to at least part of visible light other than the visible light of the first color.

In addition, the transmittance of the light absorption layer 3 at the maximum light-emission luminance wavelength of the visible light EL-emitted by the light-emitting layer 6a is, for example, preferably higher than 50% and more preferably higher than 80%. Furthermore, the absorptance of the light absorption layer 3 for the visible light other than the EL-emission wavelengths produced by the light-emitting layer 6a is, for example, the absorptance for at least part of visible light other than the EL-emission wavelengths, is preferably higher than 50% and more preferably higher than 70%.

As described above, the light absorption layer 3 covers at least the entire reflective layer 2 in the light-emitting region 9 (in other words, the entire top face of the reflective layer 2 in the light-emitting region 9). This covering of the entire reflective layer 2 by the light absorption layer 3 in the light-emitting region 9 enables the light absorption layer 3 to absorb much of the external light 10 reflected off the reflective layer 2. Therefore, the external light 10 can be restrained from being reflected (reflection of external light is restrained). In addition, the light absorption layer 3, as described above, has a high transmittance for the emission wavelength produced by the light-emitting layer 6a. Therefore, the emission wavelength is restrained from being absorbed, which enables maintaining a high front-direction luminance. Therefore, the present embodiment can provide the light-emitting element 101 that can improve contrast in the regular-reflection direction and that can maintain high display quality even under the external light 10.

in the present embodiment, the light absorption layer 3 additionally serves as a planarization layer for the planarization of the projections and depressions of the reflective layer 2 in the light-emitting region 9. The top face of the light absorption layer 3 in the light-emitting region 9 is flatter than the bottom face of the light absorption layer 3. The light absorption layer 3 has a thickness ta in portions thereof that cover the depressions 14 in the reflective layer 2 in the light-emitting region 9 and a thickness tb in portions thereof that cover portions other than the depressions 14 in the reflective layer 2 in the light-emitting region 9, the thickness ta being larger than the thickness tb.

This provision of the light absorption layer 3 such that ta>tb more reliably enables the light absorption layer 3 to absorb the external light 10 reflected off, for example, the inclined inner wall faces 13 (inclined face portion) and/or the edges of the depressions 14 in the reflective layer 2. In addition, the provision of the light absorption layer 3 such that ta>tb enables increasing the thickness of the light absorption layer 3 in the depressions 14, which renders the light absorption layer 3 less likely to come off.

A material for the light absorption layer 3 may be, for example, a mixture of a resin and a light absorbent that absorbs visible light.

The light absorbent is, for example, a pigment, an organic pigment, a dichromatic pigment, and metal nanoparticles. The pigment is, for example, a metal compound, lake pigment, or a color pigment. The metal compound is, for example, a metal compound such as an oxide, a sulfide, a sulfate, or a chromate. The organic pigment is, for example, a phthalocyanine-based pigment, a porphyrin-based pigment, or a squarylium-based pigment. The dichromatic pigment is, for example, a dichromatic pigment such as an azo-based dye, an anthraquinone-based dye, a quinophthalone-based dye, or a dioxazine-based dye. The metal nanoparticles are, for example, plasmon-absorbing metal nanoparticles. Any one of these light absorbents may be used alone; alternatively, two or more of the absorbents may be used in the form of mixture where appropriate.

Among these mixtures of light absorbents and resins, the material for the light absorption layer 3 is preferably, for example, a resin mixed with a pigment or a high-refractive-index resin mixed with an organic pigment.

The high-refractive-index resin is, for example, any one of various conventional resins known as high-refractive-index resins. Typical resins have a refractive index of approximately 1.5, whereas the high-refractive-index resin is, for example, a resin that has a higher refractive index than typical resins, such as a resin with a refractive index of 1.6 or higher. The high-refractive-index resin is, for example, a high-refractive-index polymer, a zirconium- or hafnium-added acrylate, a high-refractive-index nanocomposite (a combination of an organic polymer matrix and a high-refractive-index inorganic nanoparticles), a polyester (typical refractive index is from 1.6), or a polyimide (typical refractive index is from 1.53 to 1.8, both inclusive). Note that the “refractive index” in the present disclosure is the absolute refractive index. In addition, the light absorption layer 3 may be made of, for example, a well-known material used to form a color filter.

In the present embodiment, preferably n1<n2 where n1 is the refractive index of the insulating layer 1 and n2 is the refractive index of the light absorption layer 3. In other words, the refractive index (n2) of the light absorption layer 3 is preferably higher than the refractive index (n1) of the insulating layer 1. This n1<n2 setting enables the insulating layer 1 to totally reflect the light that is incident to the light absorption layer 3 in oblique directions at angles (angles of incidence) greater than or equal to the total reflection angle (critical angle). Therefore, the n1<n2 setting enables further improving external light-extraction efficiency.

Note that the refractive index (n2) of the light absorption layer 3 is preferably, for example, from 1.5 to 1.8, both inclusive. The refractive index (n1) of the insulating layer 1 is preferably, for example, from 1.0 to 1.6, both inclusive.

In the present embodiment, since the depressions 16 are formed in the surface of the insulating layer 1 as described above, the insulating layer 1 is made of an organic insulating material.

The organic insulating material used in the insulating layer 1 is, for example, a photoresist containing, as a base resin, for example, an acrylic resin (typical refractive index is from 1.48 to 1.5), polyethylene (typical refractive index is from 1.54), polyethylene terephthalate (typical refractive index is from 1.57 to 1.58), polytetrafluoroethylene (typical refractive index is from 1.35), or polyimide. Note that when the insulating layer 1 is made of a polyimide, a polyimide that satisfies n1<n2 is used. In addition, when the insulating layer 1 is made of a polyimide as described above, the polyimide used preferably has a refractive index of 1.6 or higher.

In addition, the insulating layer 1 is preferably absorptive to visible light. Therefore, the insulating layer 1 may contain a light absorbent that is absorptive to visible light. This light absorbent is, for example, carbon black. In addition, the light absorbent may be, for example, the same absorbent as the absorbent used in the light absorption layer 3.

The insulating layer 1 being absorptive to visible light as described above enables not only the light absorption layer 3, but also the insulating layer 1, to absorb the external light 10. Therefore, the insulating layer 1 having such a visible-light-absorbing property enables further restraining reflection of the external light 10, which further improves contrast under external light.

The light-emitting element 101, as an example, electrically connects the first electrode 4 to a TFT on the substrate, by the reflective layer 2, which covers the depression 16 that additionally serves as the contact hole CH, being connected to the first electrode 4 in a layer overlying the insulating layer 1 in a portion that is out of the light-emitting region 9. The reflective layer 2 electrically connects the first electrode 4 to a TFT on the substrate in this manner. Therefore, the reflective layer 2 is preferably made of an electrically conductive, light-reflective material.

The light-reflective material is preferably a material that has a high reflectance to visible light and may be, for example, a metal material. Specific examples include Al (aluminum; typical refractive index is 1.39) and Ag (silver; typical refractive index is 1.35). These materials have high reflectance to visible light and hence improve luminous efficiency.

In addition, in the present embodiment, preferably n1<n2<n3 where n3 is an average refractive index of the layers from the first electrode 4 through the second electrode 7 in the light-emitting region 9. In other words, the average refractive index (n3) of the layers from the first electrode 4 through the second electrode 7 in the light-emitting region 9 is preferably higher than the refractive index (n2) of the light absorption layer 3 and the refractive index (n1) of the insulating layer 1.

As described above, the n1<n2 setting enables the insulating layer 1 to totally reflect the light that is incident to the light absorption layer 3 in oblique directions at angles (angles of incidence) greater than or equal to the total reflection angle (critical angle). In addition, the n2<n3 setting completely inhibits the light reflected off the insulating layer 1 or the reflective layer 2 from being totally reflected off the interface between the light absorption layer 3 and the first electrode 4, regardless of the angle at which this light hits the interface, which renders the light more likely to be transmitted through the layers from the first electrode 4 through the second electrode 7 and discharged to the outside. Therefore, the n1<n2<n3 setting enables further improving external light-extraction efficiency.

Note that the “average refractive index” of the layers from the first electrode 4 through the second electrode 7 in the light-emitting region 9 is an average value of the refractive index of the first electrode 4, the refractive index of the functional layer 6, and the refractive index of the second electrode 7. The average refractive index (n3) of the layers from the first electrode 4 through the second electrode 7 in the light-emitting region 9 is, for example, from 1.6 to 2.5, both inclusive.

A description is given next of the layers from the first electrode 4 through the second electrode 7.

One of the first electrode 4 and the second electrode 7 is an anode, and the other is a cathode. Note that either one of the first electrode 4 and the second electrode 7 may be an anode, and the other may be a cathode.

Both the first electrode 4 and the second electrode 7 are made of a light-transmitting material. This light-transmitting material may be, for example, tin-doped indium oxide (ITO), zinc-doped indium oxide (IZO), aluminum-doped zinc oxide (AZO), gallium-doped zinc oxide (GZO), antimony-doped tin oxide (ATO), silver nanowires, graphene, or PEDOT:PSSS (a complex of (poly(3,4-ethylenedioxythiophene) and poly(4-styrene sulfonate)). These materials are transparent to visible light and has a high transmittance to visible light, thereby improving luminous efficiency.

As described above, the first electrode 4 and the second electrode 7 are disposed sandwiching the functional layer 6.

The light-emitting layer 6a contains a light-emitting material that emits the light 8 as EL (electroluminescence) light upon recombination of the electrons transported from the cathode and the holes transported from the anode. The light 8 is monochromatic (first color) visible light.

The light-emitting layer 6a EL-emits light by the electric current that flows between the first electrode 4 and the second electrode 7. The light-emitting element 101 is a top-emission display element, and both the first electrode 4 and the second electrode 7 are transparent to visible light.

Note that the light-emitting element 101 may be, for example, a QLED or an OLED.

When the light-emitting element 101 is a QLED, the light-emitting layer 6a contains, for example, nanosized quantum dots (semiconductor nanoparticles) as a light-emitting material. Quantum dots are hereinafter referred to as “QDs.”

The aforementioned QDs may be publicly known QDs. The QDs may contain, for example, at least one semiconductor material composed of at least one element selected from the group consisting of Cd (cadmium), S (sulfur), Te (tellurium), Se (selenium), Zn (zinc), In (indium), N (nitrogen), P (phosphorus), As (arsenic), Sb (antimony), aluminum (Al), Ga (gallium), Pb (lead), Si (silicon), Ge (germanium), and Mg (magnesium). In addition, the QDs may have a two-component core structure, a three-component core structure, a four-component core structure, a core-shell structure or a core-multishell structure. In addition, the QDs may contain nanoparticles doped with at least one of the elements listed here and may have a composition gradient structure.

When the light-emitting layer 6a contains QDs as a light-emitting material, the wavelengths of the light 8 emitted by the light-emitting layer 6a, in other words, the color of the light 8 emitted by the light-emitting layer 6a, is controllable by suitably adjusting the particle diameter and composition of the QDs.

Meanwhile, when the light-emitting element 101 is an OLED, the light-emitting layer 6a is made of, for example, an organic light-emitting material such as a low-molecular fluorescent pigment or a metal complex. Note that the organic light-emitting material may be either a phosphorescent material or a fluorescent material. In addition, the light-emitting layer 6a may be made of a two-component material containing a host material for transporting holes and electrons and a light-emitting dopant material for emitting light as a light-emitting material and may be made of a light-emitting material alone. The organic light-emitting material may be, for example, an organic light-emitting material that emits visible light of a desired color as the light 8.

When the light-emitting element 101 is a QLED, electrons and holes recombine in the light-emitting layer 6a due to a drive current between the first electrode 4 and the second electrode 7, which generates excitons that emit light upon transitioning from the conduction band energy level to the valence band energy level of the QDs.

When the light-emitting element 101 is an OLED, electrons and holes recombine in the light-emitting layer 6a due to a drive current between the first electrode 4 and the second electrode 7, which generates excitons that emit light upon transitioning to the ground state.

It should be understood however that the light-emitting element 101 may be a light-emitting element other than the OLED and the QLED and may be, for example, an IOLED (inorganic light-emitting diode).

The light-emitting element 101 may be a blue light-emitting element that emits blue light as the light 8, a green light-emitting element that emits green light as the light 8, or a red light-emitting element that emits red light as the light 8.

The following description assumes, as an example, that the light-emitting element 101 is a QLED. When the light-emitting element 101 is a blue light-emitting element, the light-emitting layer 6a contains blue QDs that emits blue light as a light-emitting material. When the light-emitting element 101 is a green light-emitting element, the light-emitting layer 6a contains green QDs that emits green light as a light-emitting material. When the light-emitting element 101 is a red light-emitting element, the light-emitting layer 6a contains red QDs that emits red light as a light-emitting material.

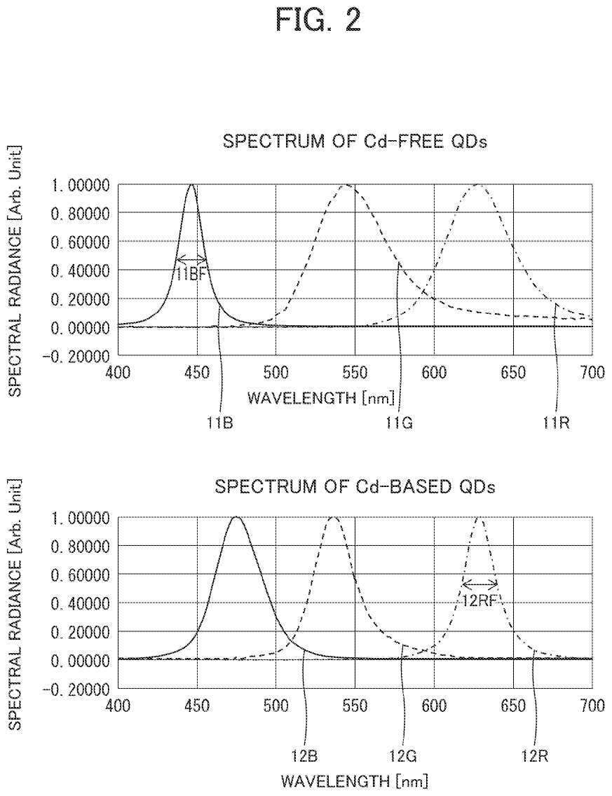

FIG. 2 is a pair of diagrams, arranged on top of the other, that represent the light-emission spectra of Cd-free QDs that practically contain no cadmium (Cd) for each color and the light-emission spectra of Cd-containing QDs for each color.

In FIG. 2, a light-emission spectrum 11B represents the light-emission spectrum of Cd-free blue QDs. A light-emission spectrum 11G represents the light-emission spectrum of Cd-free green QDs. A light-emission spectrum 11R represents the light-emission spectrum of Cd-free red QDs. In addition, a light-emission spectrum 12B represents the light-emission spectrum of Cd-based blue QDs. A light-emission spectrum 12G represents the light-emission spectrum of Cd-based green QDs. A light-emission spectrum 12R represents the light-emission spectrum of Cd-based red QDs.

Note that in the present embodiment, blue light refers to, for example, light that has a maximum light-emission luminance wavelength in the wavelength range of from 400 nm to 500 nm, both inclusive. In addition, green light refers to, for example, light that has a maximum light-emission luminance wavelength in the wavelength range of from 500 nm exclusive to 600 nm inclusive. In addition, red light refers to, for example, light that has a maximum light-emission luminance wavelength in the wavelength range of from 600 nm exclusive to 700 nm inclusive.

Both the Cd-free blue QDs represented by the light-emission spectrum 11B and the Cd-containing blue QDs represented by the light-emission spectrum 12B in FIG. 2 have, as an example, a maximum light-emission luminance wavelength in the wavelength range of from 440 nm to 480 nm, both inclusive. Both the Cd-free green QDs represented by the light-emission spectrum 11G and the Cd-containing green QDs represented by the light-emission spectrum 12G in FIG. 2 have, as an example, a maximum light-emission luminance wavelength in the wavelength range of from 530 nm to 560 nm, both inclusive. Both the Cd-free red QDs represented by the light-emission spectrum 11R and the Cd-containing red QDs represented by the light-emission spectrum 12R in FIG. 2 have, as an example, a maximum light-emission luminance wavelength in the wavelength range of from 610 nm to 640 nm, both inclusive.

Note that in the present embodiment, the full width at half maximum of the light-emission spectrum of the visible light emitted by the light-emitting layer 6a is preferably less than or equal to 50 nm. FIG. 2 shows, as an example, the light-emission spectrum 11B having a full width at half maximum 11BF that is smaller than 50 nm and the light-emission spectrum 12R having a full width at half maximum 12RF that is smaller than 50 nm. It should be understood however that the examples shown in FIG. 2 are mere examples and that the present embodiment is not limited to these examples. In addition, FIG. 2 shows only examples in which the light- emitting element 101 is a QLED and the light-emitting layer 6a contains QDs. However, when the light-emitting element 101 is, for example, an OLED or IOLED, and the light-emitting layer 6a contains a light-emitting material other than QDs, the full width at half maximum of the light-emission spectrum for the light-emitting layer 6a is still preferably less than or equal to 50 nm. A known organic material for which the full width at half maximum of the light-emission spectrum is less than or equal to 50 nm is, for example, DABNA, which is a material for thermally activated delayed fluorescent bodies.

This small full width at half maximum of the light 8, which is EL light, reduces the absorption by the light absorption layer 3, which enables brighter displays.

In addition, if the wavelength range of the visible light region, which is from 400 nm to 700 nm, is divided roughly into blue, green, and red as described above, the wavelength range for each color has a width of approximately 100 nm as described above. If the full width at half maximum of the light 8 is reduced to or below half the wavelength range for each color, it becomes easier to strike a balance between the transmission of the light 8 and the absorption of the external light 10 in the light absorption layer 3.

Note that FIG. 1 shows the functional layer 6 being the light-emitting layer 6a as an example of the simplest structure for convenience of illustration. However, the present embodiment is not limited to this example. The functional layer 6 may, where necessary, include at least one of a hole injection layer for injecting holes between the anode and the light-emitting layer 6a, a hole transport layer for transporting holes in the light-emitting layer 6a, an electron injection layer for injecting electrons between the cathode and the light-emitting layer 6a, and an electron transport layer for transporting electrons in the light-emitting layer 6a. The functional layer 6 may additionally include layers other than these layers.

The first electrode 4 has an edge thereof covered by the electrically insulating edge cover 5. The edge cover 5 is provided, surrounding the patterned first electrode 4, on a face of the first electrode 4 opposite the light absorption layer 3 (in other words, on the first electrode 4) so as to cover the edge of the first electrode 4. This edge cover has an opening serving as the light-emitting region 9 of the light-emitting element 101.

The edge cover 5 absorbs or blocks visible light. The edge cover 5 is made of, for example, a photosensitive resin to which a light absorbent such as carbon black has been added. The photosensitive resin is, for example, a polyimide, acrylic resin, or like photosensitive organic insulating material.

As described above, the portion of the reflective layer 2 that is out of the light-emitting region 9 is directly or indirectly covered at least by the edge cover 5 and optionally also by the light absorption layer 3. Meanwhile, the reflective layer 2 in the light-emitting region 9 is covered by the light absorption layer 3. Therefore, in the present embodiment, the entire surface of the reflective layer 2 on the first electrode 4 side is covered by the light absorption layer 3 or the edge cover 5. Therefore, the present embodiment is capable of restraining the reflection of the external light 10 across the entire reflective layer 2.

As described here, at least a portion of the reflective layer 2 that is out of the light-emitting region 9 may be covered by the edge cover 5 instead of by the light absorption layer 3. The portion of the reflective layer 2 that is out of the light-emitting region 9 is not necessarily covered by the light absorption layer 3.

Light 8a that is part of the light 8 emitted by the light-emitting layer 6a that is incident to the second electrode 7 at an angle of incidence smaller than the total reflection angle (critical angle) is transmitted through the second electrode 7 and discharged outside the light-emitting element 101. Light 8b, which is part of the light 8 emitted by the light-emitting layer 6a that is incident to the light absorption layer 3 through the first electrode 4, is transmitted through the light absorption layer 3 and reflected off the reflective layer 2. Light 8c, which is part of the light 8 emitted by the light-emitting layer 6a that is incident to the second electrode 7 at an angle of incidence greater than or equal to the total reflection angle (critical angle), is totally reflected off an interface of the second electrode 7 opposite the functional layer 6, transmitted through the second electrode 7, the functional layer 6, the first electrode 4, and the light absorption layer 3, and reflected off the reflective layer 2.

As described above, the light absorption layer 3 has a higher transmittance to light of a maximum light-emission luminance wavelength of the visible light of a color (first color) of the light emitted at least by the light-emitting layer 6a than to at least part of visible light other than the visible light of the first color. Therefore, for example, the maximum light-emission luminance wavelength of the visible light of the color (first color) of the light emitted by the light-emitting layer 6a is equal to the maximum transmission wavelength in the visible light wavelength range (hereinafter, “maximum visible light transmission wavelength”) of the light absorption layer 3. Therefore, the light 8b and the light 8c reflected off the reflective layer 2 is transmitted through the light absorption layer 3, the first electrode 4, the functional layer 6, and the second electrode 7 and discharged outside the light-emitting element 101.

As described here, the light-emitting element 101 enables reflecting the light 8b and the light 8c emitted by the light-emitting layer 6a off the reflective layer 2 for external extraction. Therefore, the light-emitting element 101 enables the extraction of the light 8a, the light 8b, and the light 8c to the outside of the light-emitting element 101, thereby improving light-extraction efficiency.

In addition, the light absorption layer 3 has a higher transmittance to light of a maximum light-emission luminance wavelength of the light of a particular color (first color) of the light emitted at least by the light-emitting layer 6a than to at least part of visible light other than the visible light of the first color. Therefore, the light-emitting element 101 can enhance color purity.

Meanwhile, the external light 10 is transmitted through the second electrode 7, the functional layer 6, and the first electrode 4 and incident to the light absorption layer 3.

In the absence of the light absorption layer 3, the external light 10 is scatteringly reflected off, for example, the inclined inner wall face 13 and/or the edge of the reflective layer 2. Therefore, the external light 10 reduces contrast both in the regular-reflection direction and in directions other than the regular-reflection direction.

However, in the present embodiment, the light absorption layer 3 can absorb part of the external light 10 transmitted through the second electrode 7, the functional layer 6, and the first electrode 4 and incident to the light absorption layer 3, the part being the visible light having wavelengths that encompass the wavelength range of the first color, but exclude the visible light in the wavelength range transmitted through the light absorption layer 3.

For instance, when the light 8 emitted by the light-emitting layer 6a is blue light having a maximum light-emission luminance wavelength thereof in the wavelength range of from 440 nm to 480 nm, both inclusive, the light absorption layer 3 is formed to have, for example, a higher transmittance to the blue light of the maximum light-emission luminance wavelength than to the visible light other than blue wavelengths and to have, for example, a maximum visible light transmission wavelength in the wavelength range of from 440 nm to 480 nm, both inclusive. In other words, the light absorption layer 3 has a maximum absorption wavelength in the visible light wavelength range (hereinafter, “maximum visible light absorption wavelength”) in a wavelength range of, for example, 480 nm or higher that is a wavelength range of visible light other than except the aforementioned wavelength range. In this example, the light absorption layer 3 absorbs green light and red light and transmits blue light. Therefore, in this example, the light absorption layer 3 in the light-emitting element 101 can absorb visible light in the wavelength band of approximately ⅔ of the total visible light wavelengths.

When the light 8 emitted by the light-emitting layer 6a is green light having a maximum light-emission luminance wavelength thereof in the wavelength range of from 530 nm to 560 nm, both inclusive, the light absorption layer 3 is formed to have, for example, a higher transmittance to the green light of the maximum light-emission luminance wavelength than to the visible light other than green wavelengths and to have, for example, a maximum visible light transmission wavelength in the wavelength range of from 530 nm to 560 nm, both inclusive. In this example, the light absorption layer 3 has such maximum visible light absorption wavelengths, for example, one in the wavelength range of below 530 nm and another in the wavelength range of above 560 nm, as to absorb blue light and red light and transmit green light. In this example, the light absorption layer 3 in the light-emitting element 101 can again absorb visible light in the wavelength band of approximately ⅔ of the total visible light wavelengths.

When the light 8 emitted by the light-emitting layer 6a is red light having a maximum light-emission luminance wavelength thereof in the wavelength range of from 610 nm to 640 nm, both inclusive, the light absorption layer 3 is formed to have, for example, a higher transmittance to the red light of the maximum light-emission luminance wavelength than to the visible light other than red wavelengths and to have, for example, a maximum visible light transmission wavelength in the wavelength range of from 610 nm to 640 nm, both inclusive. In this example, the light absorption layer 3 has such a maximum visible light absorption wavelength, for example, in the wavelength range of below 610 nmnm, as to absorb blue light and green light and transmit red light. In this example, the light absorption layer 3 in the light-emitting element 101 can again absorb visible light in the wavelength band of approximately ⅔ of the total visible light wavelengths.

It should be understood however that the present embodiment is not limited to this example. As described above, the light absorption layer 3 needs only to be specified at least to have a higher transmittance to light of the maximum light-emission luminance wavelength of the visible light of the first color than to at least part of visible light other than the visible light of the first color. In other words, the light absorption layer 3 needs only to be specified at least to have a higher transmittance to the light in a particular wavelength range that encompasses the maximum light-emission luminance wavelength of a particular color (first color) of the light emitted at least by the light-emitting layer 6a than to at least part of visible light other than the visible light of the first color.

Human eyes are less sensitive to red light and blue light than to green light. Therefore, the light absorption layer 3 may be formed so as to, for example, transmit red light and blue light and absorb only green light, which is more visually recognizable.

Therefore, when the light 8 emitted by the light-emitting layer 6a is either blue light having a maximum light-emission luminance wavelength in the wavelength range of from 440 nm to 480 nm, both inclusive, or red light having a maximum light-emission luminance wavelength in the wavelength range of from 610 nm to 640 nm, both inclusive, the light absorption layer 3 may be formed so as to have, for example, maximum visible light transmission wavelengths, one in the wavelength range of from 440 nm to 480 nm, both inclusive, and another in the wavelength range of from 610 nm to 640 nm, both inclusive, and a maximum visible light absorption wavelength in the wavelength range of from 530 nm to 560 nm, both inclusive. In this example, the light absorption layer 3 in the light-emitting element 101 can absorb visible light in the wavelength band of approximately ⅓ of the total visible light wavelengths.

As described here, in the present embodiment, the light absorption layer 3 can absorb much of the external light 10 that is transmitted through the second electrode 7, the functional layer 6, and the first electrode 4 and incident to the light absorption layer 3. The light absorption layer 3 in the light-emitting element 101 can absorb, especially, much of the external light 10 reflected off, for example, the inclined inner wall face 13 (inclined face portion) and/or the edge of the reflective layer 2. Therefore, the light-emitting element 101 can restrain the reflection of the external light 10 off the reflective layer 2, improving contrast both in the regular-reflection direction and in directions other than the regular-reflection direction of the external light 10. Therefore, the light-emitting element 101 can further improve ambient contrast ratio and enables extracting more of the light 8 emitted by the light-emitting layer 6a in the front direction even under external light by means of the reflective layer 2 while maintaining display quality. Therefore, the light-emitting element 101 can maintain high front-direction luminance and achieve brighter displays.

### Variation Example

Note that FIG. 1 shows as an example the insulating layer 1 and the reflective layer 2 forming a reflective structural body that has projections and depressions in the surface thereof. However, the present embodiment is not limited to this example.

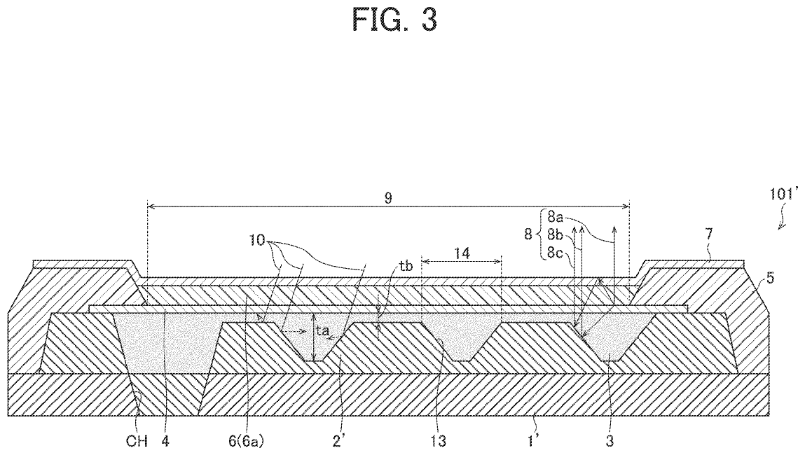

FIG. 3 is a schematic cross-sectional view and a plan view of a structure of a light-emitting element 101′ in accordance with the present variation example.

The light-emitting element 101′ differs from the light-emitting element 101 as described below and has otherwise the same structure as the light-emitting element 101.

The light-emitting element 101′ in accordance with the present variation example includes: an insulating layer 1′ in place of the insulating layer 1; and a reflective layer 2′ in place of the reflective layer 2.

The insulating layer 1′ is a planarization film and has no depressions in the surface thereof except for the contact hole CH. In contrast, the reflective layer 2′ is formed thicker than the reflective layer 2 and has formed in the surface thereof a plurality of depressions 14 (e.g., four depressions 14) each with an inclined inner wall face 13 in the light-emitting region 9 of the light-emitting element 101. In other words, the reflective layer 2′ has a combined shape of the insulating layer 1 and the reflective layer 2 of the light-emitting element 101.

Therefore, the light-emitting element 101′ can achieve the same effects as the light-emitting element 101.

Note that in the present variation example, the reflective layer 2′ forms a reflective structural body. As described here, the reflective structural body does not necessarily include an insulating layer.

In addition, as described above, the insulating layer 1′ is a planarization film. Therefore, for example, when the substrate as a support body includes a planarization film on the surface thereof, for example, when the substrate is an array substrate including a planarization film covering TFTs, the insulating layer 1′ may be a planarization film on the surface of the substrate, and the light-emitting element 101′ does not necessarily include an insulating film.

Note that FIG. 3 shows as an example the reflective layer 2′ having a plurality of depressions 14 in the light-emitting region 9. However, in the present variation example, at least one depression 14 needs only to be provided in the light-emitting region 9 similarly to the previous example.

### Embodiment 2

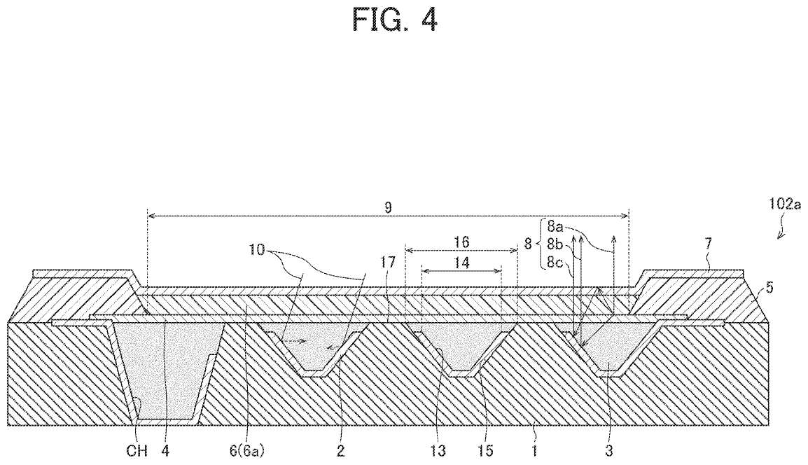

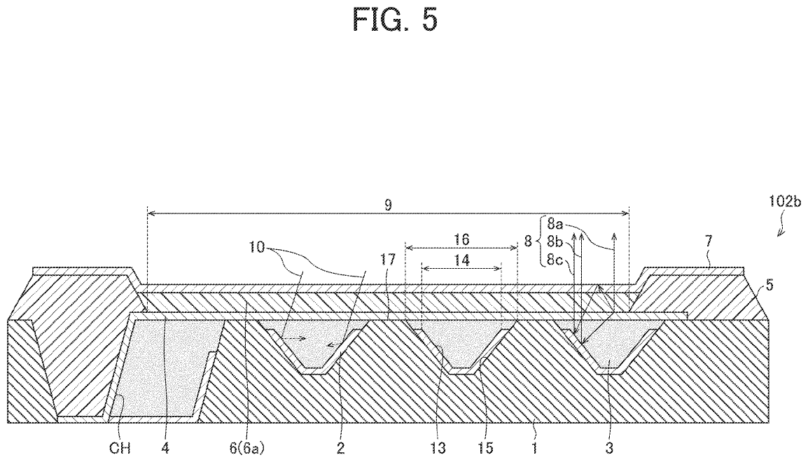

FIG. 4 is a schematic cross-sectional view of a structure of a light-emitting element 102a in accordance with the present embodiment. FIG. 5 is a schematic cross-sectional view of a structure of another light-emitting element 102b in accordance with the present embodiment.

The light-emitting element 102a differs from the light-emitting element 101 as described below and the light-emitting element 102b has the same structure as the light-emitting element 101 except for the points given below.

In the light-emitting element 101, the reflective layer 2 covers the entire inner wall face 15 of each of the plurality of depressions 16 in the insulating layer 1. Therefore, in the light-emitting element 101, the reflective layer 2 covers the entire inner wall face 15 of each of the plurality of depressions 16 in the insulating layer 1 in the light-emitting region 9. In contrast, referring to FIG. 4, in the light-emitting element 102a, the reflective layer 2 covers a part of the inner wall face 15 of each depression 16 in the insulating layer 1 in the light-emitting region 9.

Specifically, in the light-emitting element 102a shown in FIG. 4, the insulating layer 1 has top portions 17 (i.e., top faces of the projections) in contact with the first electrode 4 in the light-emitting region 9, each portion 17 being located between two adjacent depressions 16 and covered neither by the reflective layer 2 nor by the light absorption layer 3. It should be understood however that FIG. 4 is a mere example and that the top portions 17 need only to be not covered by the reflective layer 2. The top portions 17 may be covered by the light absorption layer 3.

Since the reflective layer 2 covers a part of the inner wall face 15 of each depression 16 in the insulating layer 1 in the light-emitting region 9, each depression 14 in the reflective layer 2 has an edge thereof formed on a middle portion of the inner wall face 15 (sloped portion) in the light-emitting region 9. Therefore, the part of the inner wall face 15 that is in the vicinity of the top portion 17 is covered not by the reflective layer 2, but by the light absorption layer 3, in the light-emitting region 9. It should be understood however that even in the light-emitting element 102a, the light absorption layer 3 covers the entire reflective layer 2 in the light-emitting region 9.

As described here, in the light-emitting element 102a, the reflective layer 2 having the depressions 14 with the inclined inner wall faces 13 covering parts of the inner wall faces 15 of the depressions 16 in the insulating layer 1 in the light-emitting region 9 reduces the area of the face off which the external light 10 is reflected. Therefore, the light-emitting element 102a can not only achieve the same effects as the light-emitting element 101, but can also further improve contrast under the external light 10.

The light-emitting element 102b differs from the light-emitting element 102a as described below and has otherwise the same structure as the light-emitting element 102a except for the points given below.

Similarly to the light-emitting element 101, in the light-emitting element 102a, the reflective layer 2 provided in at least one of the depressions 16 that additionally serves as the contact hole CH is connected to the first electrode 4 under the edge cover 5 by being extended to a layer overlying the insulating layer 1 in a portion that is out of the light-emitting region 9. Hence, the first electrode 4 and the TFT on the substrate are electrically connected by the reflective layer 2.

In contrast in the light-emitting element 102b, referring to FIG. 5, the first electrode 4 and the TFT on the substrate are electrically connected by the first electrode 4 being extended into the depression 16 that additionally serves as the contact hole CH.

In addition, in the light-emitting element 101, the reflective layer 2 covers the entire inner wall face 15 even in a portion that is out of the light-emitting region 9, as a result of the reflective layer 2 covering the entire inner wall faces 15 of the plurality of depressions 16 in the insulating layer 1. Referring to FIG. 4, in the light-emitting element 102a, the reflective layer 2 covers only a part of the inner wall face 15 of each depression 16 in the insulating layer 1 in the light-emitting region 9. However, as described above, the reflective layer 2 in the depression 16 that additionally serves as the contact hole CH is extend to a layer overlying the insulating layer 1 in a portion that is out of the light-emitting region 9. Therefore, in the light-emitting element 102a, similarly to the light-emitting element 101, the reflective layer 2 covers the inner wall faces 15 in a portion that is out of the light-emitting region 9.

In contrast, in the light-emitting element 102b, referring to FIG. 5, the inner wall face 15 has a part thereof covered neither by the reflective layer 2 nor by the light absorption layer 3 in a portion that is out of the light-emitting region 9, as a result of the first electrode 4 being extended into the depression 16 that additionally serves as the contact hole CH. This part is covered by the edge cover 5.

In the light-emitting element 102b shown in FIG. 5, the edge cover 5 does not need to be absorptive to visible light because the entire reflective layer 2 is covered by the light absorption layer 3.

Note that in both the light-emitting element 102a and the light-emitting element 102b, similarly to the light-emitting element 101, the reflective layer 2 itself in a portion that is out of the light-emitting region 9 is directly or indirectly covered at least by the edge cover 5 (detailed later) and optionally also by the light absorption layer 3. In addition, even in the light-emitting element 102b, the light absorption layer 3 covers the entire reflective layer 2 in the light-emitting region 9.

Even in the light-emitting element 102b, the reflective layer 2 having the depressions 14 with the inclined inner wall faces 13 covering parts of the inner wall faces 15 of the depressions 16 in the insulating layer 1 in the light-emitting region 9 reduces the area of the face off which the external light 10 is reflected. Therefore, the light-emitting element 102b can also not only achieve the same effects as the light-emitting element 101, but can also further improve contrast under the external light 10.

### Embodiment 3

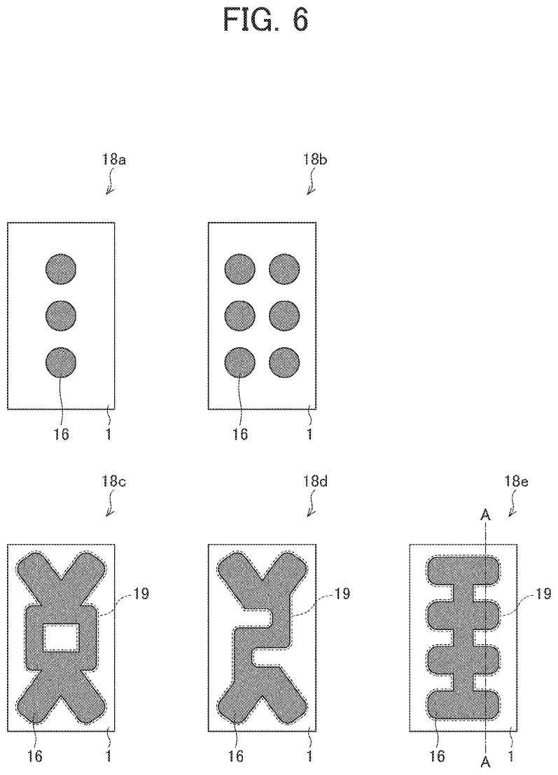

FIG. 6 is a set of plan views, arranged next to each other, of five examples of the depression 16 formed in the insulating layer 1. FIG. 6 represent five insulating layer structures 18a to 18e. The insulating layer structures 18a to 18e show only the insulating layer 1 and the depressions 16 for convenience of illustration.

When there are provided a plurality of depressions 16, the plurality of depressions 16 may be arranged in a single array of islands as in the insulating layer structure 18a and may be arranged in a plurality of arrays of islands as in the insulating layer structure 18b.

In addition, the depressions 16 may have at least a linear portion 19 that is a linearly formed region as shown in the insulating layer structure 18c to 18e. This structure facilitates the application of the material that constitutes the light absorption layer 3 and enables reliably covering the edge of the reflective layer 2. In addition, the light absorption layer 3 having a contiguously formed increased-thickness portion covering the depressions 16 in the insulating layer 1 on which the reflective layer 2 is provided renders the light absorption layer 3 less likely to come off.

The light absorption layer 3 is less likely to come off when the plurality of depressions 16 are contiguous than when a plurality of small circular depressions 16 are separately provided. The inner wall faces 15 account for a higher ratio, and the structure for reflecting light in the front direction has an increased area, when the plurality of depressions 16 have a complex shape. Furthermore, the depressions 16 are more effective when branching out.

Note that, for example, the cross-section of the insulating layer structure 18e taken along line A-A may have, as an example, the same shape as the cross-sectional shape of the insulating layer 1 shown in FIG. 1, FIG. 4, or FIG. 5.

### Embodiment 4

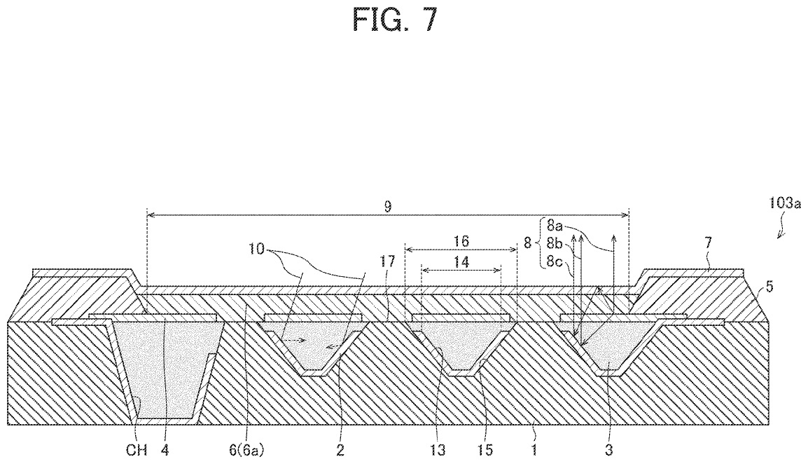

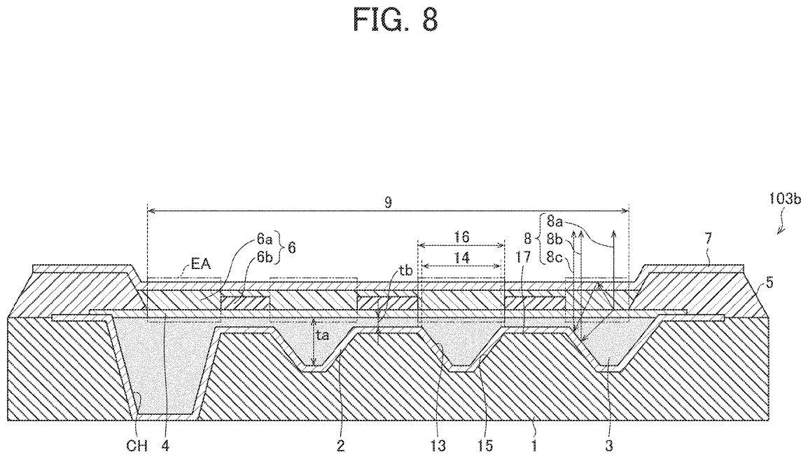

FIG. 7 is a schematic cross-sectional view of a structure of a light-emitting element 103a in accordance with the present embodiment. FIG. 8 is a schematic cross-sectional view of a structure of another light-emitting element 103b in accordance with the present embodiment. Note that the insulating layer 1 may again have, for example, the same plan-view shape as the insulating layer structure 18e even in the examples shown in FIG. 7 and FIG. 8.

The light-emitting element 103a differs from the light-emitting element 102a as described below and has otherwise the same structure as the light-emitting element 102a except for the points given below. It should be understood however that the present embodiment is not limited to this example and that the light-emitting element 103a may differ in structure from the light-emitting element 102b in the points given below.

Referring to FIG. 7, similarly to the light-emitting element 102a, in the light-emitting element 103a, the reflective layer 2 covers parts of the inner wall faces 15 of the depressions 16 in the insulating layer 1 in the light-emitting region 9. It should be understood however that in the light-emitting element 103a, no first electrode 4 is provided in portions of the light-emitting region 9 in which no reflective layer 2 is provided. In other words, the first electrode 4 is provided only in portions of the light-emitting region 9 that overlap the reflective layer 2 in a plan view.

Therefore, in the light-emitting element 102a, the top portions 17 of the insulating layer 1 (i.e., the top faces of the projections), each of which is located between two adjacent depressions 16, are in contact with the first electrode 4 in the light-emitting region 9, whereas in the light-emitting element 103a, the top portions 17 are in contact with the functional layer 6 in the light-emitting region 9.

When the reflective layer 2 covers not the entire inner wall faces 15 of the depressions 16, but parts of the inner wall faces 15, in the light-emitting region 9, the light-extraction efficiency is low in the portions of the light-emitting region 9 in which no reflective layer 2 is provided.

As described here, no first electrode 4 is provided in the portions of the light-emitting region 9 in which no reflective layer 2 is provided and also in which the light-extraction efficiency is low. This particular structure can not only achieve the same effects as the light-emitting element 102a, but can also restrain power consumption by allowing only the regions in which the light-extraction efficiency is high to emit light. In addition, the structure can improve the light-extraction efficiency of the portions in which the first electrode 4 is provided.

Note that as described above, the insulating layer 1 shown in FIG. 7 has, for example, the same plan-view shape as the insulating layer structure 18e shown in FIG. 6. Therefore, although the reflective layer 2 in the depressions 16 and the first electrode 4 overlapping the reflective layer 2 in the cross-section shown in FIG. 7 appear to be separated from each other in the cross-section, the reflective layer 2 and the first electrode 4 in the cross-section are, needless to say, connected in a cross-section other than FIG. 7.

In addition, similarly to the light-emitting element 102a, in the light-emitting element 103a, each depression 14 in the reflective layer 2 in the light-emitting region 9 has an edge thereof formed on a middle portion of the inclined inner wall face 15 of the depression 16 in the insulating layer 1. Therefore, the reflective layer 2 in the light-emitting region 9 is formed slightly smaller than, for example, the depression 16 in the insulating layer 1 in a plan view and is geometrically similar to the depression 16 in a plan view. Therefore, the first electrode 4 has, for example, a geometrically similar, slightly smaller shape than the depression 16 in the insulating layer structure 18e shown in FIG. 6, and the edge cover 5 may have an opening that has a shape geometrically similar to the depression 16. In other words, the light-emitting region 9 may have a geometrically similar, slightly smaller shape than the depression 16 in the insulating layer structure 18e shown in FIG. 6.

It should be understood however that the present embodiment is not limited to this example. The light-emitting region 9 may have, for example, a geometrically similar, slightly smaller shape than the depression 16 in the insulating layer structure 18c or the insulating layer structure 18d shown in FIG. 6. In addition, the light-emitting region 9 may have, for example, a shape obtained by slightly reducing in size, and linking together, the depressions 16 in the insulating layer structure 18a or the insulating layer structure 18b shown in FIG. 6.

The light-emitting element 103b differs from the light-emitting element 103a as described below and has otherwise the same structure as the light-emitting element 103a except for the points given below.

Referring to FIG. 8, similarly to the light-emitting element 101, in the light-emitting element 103b, the reflective layer 2 covers the entire inner wall faces 15 of the depressions 16 in the insulating layer 1. Therefore, similarly to the light-emitting element 101, the reflective layer 2 in the light-emitting region 9 is covered by the light absorption layer 3.

In such a structure, the light emitted obliquely downward by a region of the light-emitting layer 6a that is above the bottom portion of the depression 16 readily reaches the inclined face of the reflective layer 2 and is reflected exactly upward because the light absorption layer 3 is thick. Therefore, the region of the light-emitting layer 6a that is above the bottom portion of the depression 16 has a high light-extraction efficiency. Meanwhile, the light emitted obliquely downward by a region of the light-emitting layer 6a that is above the top portion 17 of the insulating layer 1 (in other words, a region that does not overlap the depression 16 in a plan view) is reflected more than once off the second electrode 7 and off the bottom face of the light absorption layer 3 because the light absorption layer 3 is thin. Therefore, the region that is above the top portion 17 of the insulating layer 1 and that does not overlap the depression 16 in a plan view has a lower light-extraction efficiency than the region that overlaps the depression 16 in a plan view.

Accordingly, in the light-emitting element 103b, an insulating layer 6b (second insulating layer) is provided between the first electrode 4 and the second electrode 7 in this low- light-extraction-efficiency region.

In other words, the functional layer 6 in the light-emitting element 103b further includes the insulating layer 6b. The insulating layer 6b is provided correspondingly to the top portions 17 in the insulating layer 1 in regions that do not overlap the depressions 16 in a plan view. In other words, the insulating layer 6b has openings corresponding to the depressions 16.

In the light-emitting element 103b shown in FIG. 8, the insulating layer 6b is provided in the low-light-extraction-efficiency regions as described here so as to restrict the current conduction regions EA only to those regions in which the light-extraction efficiency is high, thereby restraining power consumption.

The insulating layer 6b can be formed by patterning an inorganic insulating film or an organic insulating film. The inorganic insulating material used in the inorganic insulating film may be, for example, silicon nitride (SiN) or silicon oxide (SiO₂). The organic insulating material used in the organic insulating film may be, for example, an electrically insulating resin listed as examples of the material for the insulating layer 1 such as an acrylic resin and a polyimide.

### Variation Example

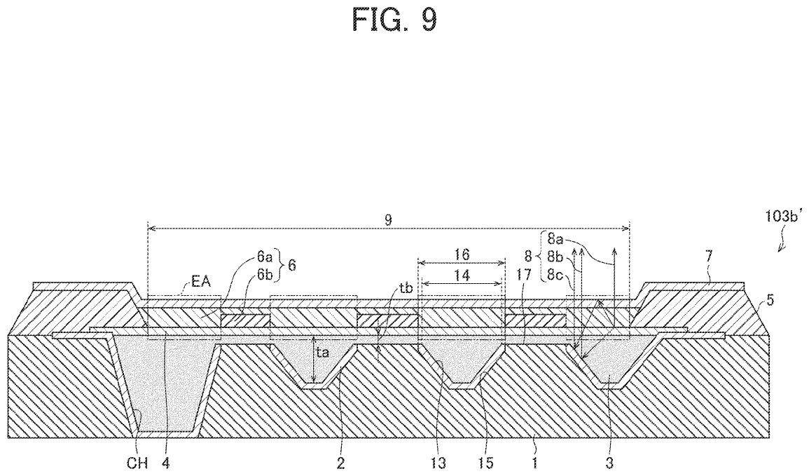

FIG. 9 is a schematic cross-sectional view of a structure of a light-emitting element 103b′ in accordance with the present variation example. Note that the insulating layer 1 may again have, for example, the same plan-view shape as the insulating layer structure 18e even in the example shown in FIG. 9.

The light-emitting element 103b′ differs from the light-emitting element 103a and the light-emitting element 103b as described below and has otherwise the same structure as the light-emitting element 103a and the light-emitting element 103b except for the points given below.

As described above, the regions of the light-emitting layer 6a that are above the top portions 17 of the insulating layer 1 (i.e., regions that do not overlap the depressions 16 in a plan view) have a reduced light-extraction efficiency because the light absorption layer 3 is thin.

Accordingly, referring to FIG. 9, in the light-emitting element 103b′, the insulating layer 6b (second insulating layer) is provided between the first electrode 4 and the second electrode 7 in these portions where the light absorption layer 3 is thin and the light-extraction efficiency is low, and no reflective layer 2 is provided in the portions. Therefore, in the light-emitting element 103b′, the reflective layer 2 covers only the inner wall faces 15 of the depressions 16 and is not provided on the top portions 17 of the insulating layer 1, in the light-emitting region 9. Therefore, in the light-emitting element 103b′, the light absorption layer 3 is provided adjacent to both the reflective layer 2 and the first electrode between the reflective layer 2 covering the depressions 16 and the first electrode 4 in regions that overlap the depressions 16 in a plan view. Meanwhile, the light absorption layer 3 is provided adjacent to both the insulating layer 1 and the first electrode between the insulating layer 1 and the first electrode 4 in regions that do not overlap the depressions 16 in a plan view and that are above the top portions 17 of the insulating layer 1.

In the light-emitting element 103b′ shown in FIG. 9, the insulating layer 6b is provided in the low-light-extraction-efficiency regions as described above so as to restrict the current conduction regions EA only to those regions in which the light-extraction efficiency is high, thereby restraining power consumption. In addition, the elimination of the reflective layer 2 in the regions where the light absorption layer 3 is thin further reduces the reflection of external light.

Note that FIG. 9 shows as an example the top portions 17 of the insulating layer 1 not covered by the reflective layer 2, but covered by the light absorption layer 3. However, the present embodiment is not limited to this example. Similarly to the light-emitting element 103a, the top portions 17 not covered by the reflective layer 2 may be formed in contact with the first electrode 4.

### Embodiment 5

FIG. 10 is a schematic cross-sectional view of a structure of a light-emitting element 104 in accordance with the present embodiment.

The following will describe differences from the light-emitting element 101. The light-emitting element 104 differs from the light-emitting element 101 as described below and has otherwise the same structure as the light-emitting element 101 except for the points given below.

In the light-emitting element 104, the insulating layer 1 and the reflective layer 2 have the contact hole CH as a depression in a portion that is out of the light-emitting region 9 (i.e., outside the light-emitting region 9), but have no projections or depressions in the light-emitting region 9. In other words, the insulating layer 1 and the reflective layer 2 each have a surface that is flat in the light-emitting region 9, and the reflective structural body has a surface that has no projections or depressions in the light-emitting region 9.

Note that although in FIG. 10, the extension of the reflective layer 2 for connecting the inner wall face of the contact hole CH and the reflective layer 2 to the first electrode 4 has a slanted face outside the light-emitting region 9, the insulating layer 1 and the reflective layer 2 do not necessarily have a slanted face.

In addition, similarly to the light-emitting element 102b, FIG. 10 shows as an example the first electrode 4 being extended to the contact hole CH so that the reflective layer 2 can electrically connect the first electrode 4 and the TFT on the substrate. However, even in the light-emitting element 104, the first electrode 4 and the TFT on the substrate may be electrically connected by the reflective layer 2, in the contact hole CH, being extended to a layer overlying the insulating layer 1 in a portion that is out of the light-emitting region 9.

Even when the surface of the reflective layer 2 has no projections or depressions in the light-emitting region 9 as described here, the light 8a, which is part of the light 8 emitted by the light-emitting layer 6a that is incident to the second electrode 7 at an angle of incidence smaller than the total reflection angle (critical angle), is transmitted through the second electrode 7 and discharged outside the light-emitting element 101. In addition, the light 8b, which is part of the light emitted by the light-emitting layer 6a that is incident to the light absorption layer 3 through the first electrode 4, is transmitted through the light absorption layer 3 and reflected off the reflective layer 2. The light 8c, which is part of the light emitted by the light-emitting layer 6a that is incident to the second electrode 7 at an angle of incidence that is greater than or equal to the total reflection angle (critical angle), is totally reflected off an interface of the second electrode 7 opposite the functional layer 6, transmitted through the second electrode 7, the functional layer 6, the first electrode 4, and the light absorption layer 3, reflected off the reflective layer 2, partially reflected off a slanted face of the reflective layer 2 outside the light-emitting region 9 in a plan view, and incidence to the second electrode 7 at a different angle.

Therefore, the light 8a, 8b, and 8c can be extracted to the outside of the light-emitting element 101 in the light-emitting element 104 as in the light-emitting element 101. Therefore, this particular structure can also improve the light-extraction efficiency, albeit not as much as can the structure in which the reflective layer 2 has the depressions 14 with the inclined inner wall face 13.

In addition, similarly to the light-emitting element 101, the light-emitting element 104 also has a higher transmittance to light of a maximum light-emission luminance wavelength of the light of a particular color (first color) of the light emitted at least by the light-emitting layer 6a than to at least part of visible light other than the visible light of the first color. Therefore, the light-emitting element 104 can enhance color purity.

In addition, the external light 10 is also transmitted through the second electrode 7, the functional layer 6, and the first electrode 4 and incident to the light absorption layer 3 in the present embodiment.

When the reflective layer 2 has no projections or depressions in the surface thereof, the external light 10 is not scatteringly reflected off, for example, the inclined inner wall face 13 and/or the edge of the reflective layer 2. Therefore, when the reflective layer 2 has no projections or depressions in the surface thereof, the contrast does not fall in directions other than the regular-reflection direction of the external light 10 even in the absence of the light absorption layer 3, but the contrast falls in the regular-reflection direction of the external light 10 in the absence of the light absorption layer 3.

However, the light absorption layer 3 can absorb much of the external light 10 transmitted through the second electrode 7, the functional layer 6, and the first electrode 4 and incident to the light absorption layer 3 in the light-emitting element 104 as in the light-emitting element 101.

Therefore, the light-emitting element 104 can restrain the reflection of the external light 10 off the reflective layer 2, improving contrast in the regular-reflection direction of the external light 10. Therefore, the light-emitting element 104 can also improve ambient contrast ratio and enables extracting more of the light 8 emitted by the light-emitting layer 6a in the front direction even under external light by means of the reflective layer 2 while maintaining display quality. Therefore, similarly to the light-emitting element 101, the light-emitting element 104 can also maintain high front-direction luminance and enables brighter displays.

### Embodiment 6

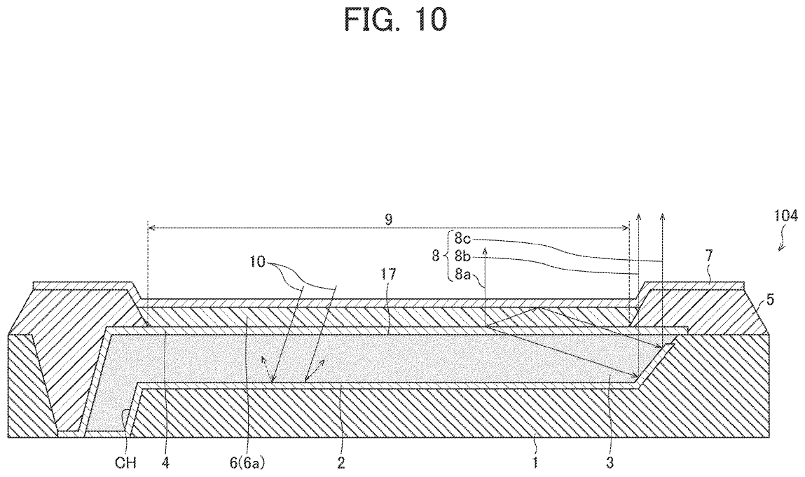

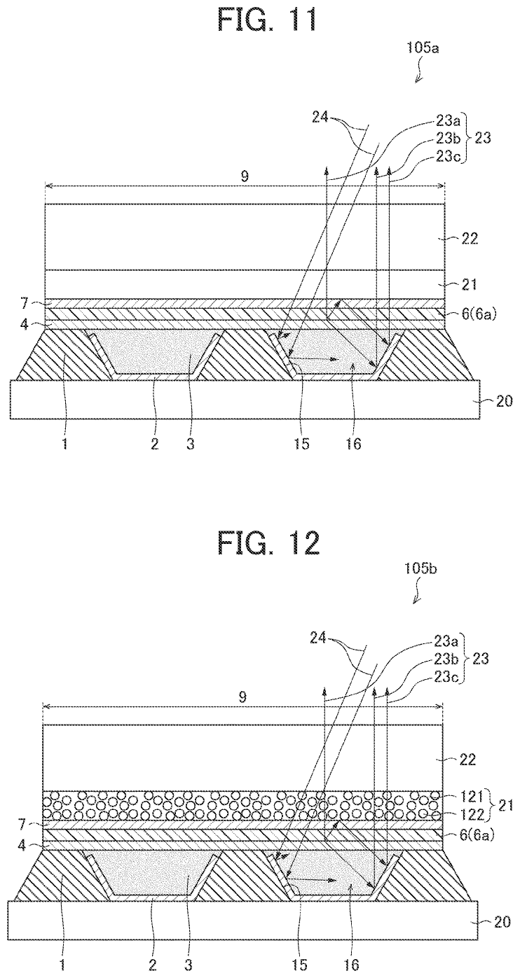

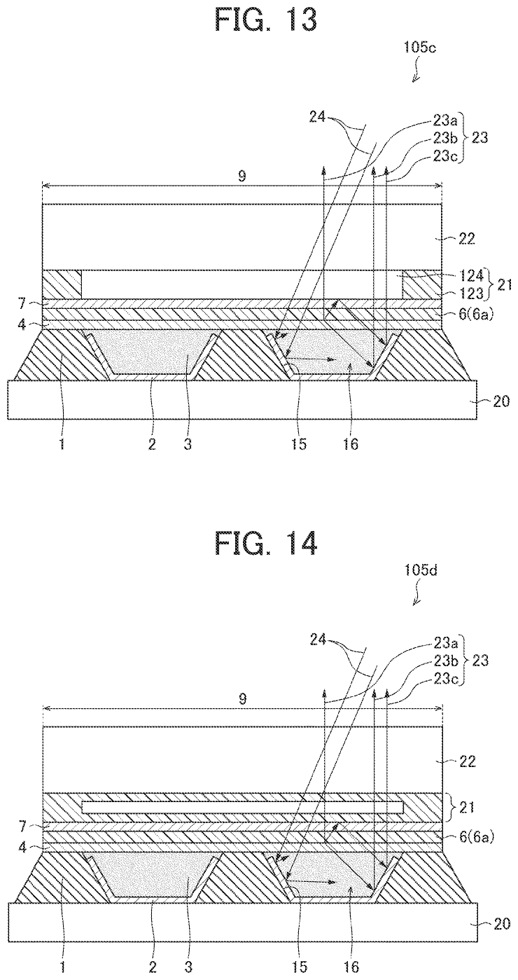

FIG. 11 is a schematic cross-sectional view of a structure of a light-emitting element 105a in accordance with the present embodiment. FIG. 12 is a schematic cross-sectional view of a structure of another light-emitting element 105b in accordance with the present embodiment. FIG. 13 is a schematic cross-sectional view of a structure of yet another light-emitting element 105c in accordance with the present embodiment. FIG. 14 is a schematic cross-sectional view of a structure of still another light-emitting element 105d in accordance with the present embodiment.

Referring to FIGS. 11 to 14, the light-emitting element 105a through the light-emitting element 105d each include a substrate 20, an insulating layer 1, a reflective layer 2, a light absorption layer 3, a first electrode 4, an edge cover 5 (not shown), a functional layer 6, a second electrode 7, a low-refractive-index layer 21, and a circular polarizer plate 22.

Note that FIG. 11 to FIG. 13 show, as an example, the insulating layer 1, the reflective layer 2, the light absorption layer 3, the first electrode 4, the edge cover 5 (not shown), the functional layer 6, and the second electrode 7 being constructed in the same manner as in, for example, the light-emitting element 102a show in FIG. 4 or the light-emitting element 102b shown in FIG. 5. Accordingly, description of these insulating layer 1 through the second electrode 7 is omitted in the present embodiment.

The low-refractive-index layer 21 is provided adjacent to a face of the second electrode 7 opposite the functional layer 6. The circular polarizer plate 22 is provided on the second electrode 7 opposite the functional layer 6 with the low-refractive-index layer 21 being interposed between the circular polarizer plate 22 and the second electrode 7. In other words, the light-emitting element 105a through the light-emitting element 105d each include the substrate 20, the insulating layer 1, the reflective layer 2, the light absorption layer 3, the first electrode 4, the edge cover 5 (not shown), the functional layer 6, the second electrode 7, the low-refractive-index layer 21, and the circular polarizer plate 22, all of which are stacked in this order.

The low-refractive-index layer 21 has a lower refractive index than the average refractive index (n3) of all the layers from the first electrode 4 through the second electrode 7. In other words, n4<n3 where n4 is the refractive index of the low-refractive-index layer 21.

In addition, as described above, the low-refractive-index layer 21 sandwiches the layers from the first electrode 4 through the second electrode 7 and is disposed on a light extraction side that is opposite the light absorption layer 3. Therefore, the refractive index (n4) of the low-refractive-index layer 21 is preferably lower than the refractive index (n2) of the light absorption layer 3 (i.e., n4<n2).

Therefore, preferably Δn3n2<Δn3n4 where Δn3n4 is the refractive index difference between the average refractive index (n3) of the layers from the first electrode 4 through the second electrode 7 and the refractive index (n4) of the low-refractive-index layer 21, and Δn3n2 is the refractive index difference between the average refractive index (n3) of the layers from the first electrode 4 through the second electrode 7 and the refractive index (n2) of the light absorption layer 3.

Note that since n4<n3 as described above, and n2<n3 as described earlier, “Δn3n2<Δn3n4” can be rewritten as “(n3−n2)<(n3−n4).”

Since Δn3n4 is greater than Δn3n2, the light that is part of light 23 emitted by the light-emitting layer 6a, the part having been incident to the low-refractive-index layer 21 in an oblique direction at an angle (angle of incidence) greater than or equal to the total reflection angle (critical angle), can be totally reflected, guided to the light absorption layer 3, and reflected off the reflective layer 2 for external extraction. Therefore, the external light-extraction efficiency can be improved. In addition, the interface reflectance at angles smaller than the total reflection angle is lower at the interface between the functional layer 6 and the light absorption layer 3 than at the interface between the functional layer 6 and the low-refractive-index layer 21, thereby enabling guiding the light 23 emitted in the functional layer 6 preferentially to the light absorption layer 3.

In addition, the refractive index (n5) of the circular polarizer plate 22 is preferably larger than the refractive index (n4) of the low-refractive-index layer 21, where n5 is the refractive index of the circular polarizer plate 22.

In addition, similarly to the low-refractive-index layer 21, the circular polarizer plate 22 is disposed closer to the light extraction side than is the light absorption layer 3, with respect to the functional layer 6 containing the light-emitting layer 6a sandwiched by the first electrode 4 and the second electrode 7. Therefore, the refractive index (n5) of the circular polarizer plate 22 is preferably smaller than the refractive index (n2) of the light absorption layer 3 (i.e., n5<n2).

Therefore, Δn2n5 is preferably larger than Δn3n2 (i.e., Δn3n2<Δn2n5) where Δn2n5 is the refractive index difference between the refractive index (n2) of the light absorption layer 3 and the refractive index (n5) of the circular polarizer plate 22.

Note that since n5<n2 as described above, and n2<n3 as described earlier, “Δn3n2<Δn2n5” can be rewritten as “(n3−n2)<(n2−n5).”

In addition, since n5<Δ2, n2, n3, n4, and n5 satisfy n4<n5<n2<n3.

The low-refractive-index layer 21 preferably has a refractive index of, for example, from 1.3 to 1.6, both inclusive (note that n4<n5<n2<n3). A reason for this is, for example, that broadly available low-refractive-index resins have a refractive index of approximately 1.3. Another reason is that if the refractive index (n4) of the low-refractive-index layer 21 exceeds 1.6, the average refractive index (n3) of the layers from the first electrode 4 through the second electrode 7 needs to be greater than or equal to 1.6, which limits structural options of the functional layer 6.

Note that the refractive index of the circular polarizer plate 22 is, for example, from 1.4 to 1.6, both inclusive.

The light-emitting element 105a shown in FIG. 11, the light-emitting element 105b shown in FIG. 12, the light-emitting element 105c shown in FIG. 13, and the light-emitting element 105d shown in FIG. 14 share the same structure except for the points given below.

In the light-emitting element 105a shown in FIG. 11, the low-refractive-index layer 21 is made of, for example, a resin with a refractive index of from 1.3 to 1.6, both inclusive (note that n4<n5<n2<n3). Examples of such a resin include acrylic resins (typical refractive index is 1.48 to 1.5), polyethylene (typical refractive index is 1.54), polyethylene terephthalate (typical refractive index is 1.57 to 1.58), polytetrafluoroethylene (typical refractive index is 1.35), and fluorine-based resins (typical refractive index is 1.40).

In the light-emitting element 105b shown in FIG. 12, the low-refractive-index layer 21 is made of a hollow-bead-containing resin in which a plurality of hollow beads 122 are contained in a resin 121. Examples of the resin 121 in which the hollow beads 122 are contained include acrylic resins and epoxy resins.

Note that the hollow beads 122 need only to include a hollow bead interior, and letting the average refractive index of the low-refractive-index layer 21 be the refractive index (n4) of the low-refractive-index layer 21, n4 needs only to satisfy n4<n5<n2<n3. Therefore, so long as these conditions are met, for example, the outer and inner diameters of the hollow beads 122 and the density of the hollow beads 122 in the resin 121 are not limited in any particular manner. Note that similarly to the resin 121, examples of the material for the hollow beads 122 include acrylic resins and epoxy resins. In addition, the resin 121 may contain bubbles, instead of being mixed with the hollow beads 122.

In the light-emitting element 105c shown in FIG. 13, the low-refractive-index layer 21 includes, for example, spacers 123 and a gas layer 124, and the low-refractive-index layer 21 in the light-emitting region 9 is formed of the gas layer 124.

In the light-emitting element 105c, the spacers 123 are formed, for example, on a member provided around a region where the low-refractive-index layer 21 is to be provided (e.g., on the second electrode 7 located above the edge cover 5), so that the spacers 123 can support the circular polarizer plate 22. Hence, the low-refractive-index layer 21 in the light-emitting region 9 is formed as a space delineated by the second electrode 7, the spacers 123, and the circular polarizer plate 22.

Note that by the spacers 123 supporting a transparent substrate (not shown), the low-refractive-index layer 21 in the light-emitting region 9 may be formed as a space delineated by the second electrode 7, the spacers 123, and this transparent substrate.

To restrain the degradation of the light-emitting layer 6a, this low-refractive-index layer 21 is preferably formed in a vacuum or in an inert gas, dry air, or other like gas. As described here, in the light-emitting region 9, the low-refractive-index layer 21 may be the gas layer 124 delineated by the aforementioned space.

In this case, n4 needs only to satisfy n4<n5<n2<n3 where the refractive index of the gas layer 124 is the refractive index (n4) of the low-refractive-index layer 21.

Note that in this case, the spacers 123 is preferably absorptive to visible light. The material for the spacers 123 is, for example, the same as the material for the edge cover 5 or the insulating layer 1 for the same reasons for the edge cover 5 or the insulating layer 1.

In the light-emitting element 105d shown in FIG. 14, the low-refractive-index layer 21 is formed hollow. In this case, n4 needs only to satisfy n4<n5<n2<n3 where the average refractive index of the low-refractive-index layer 21 is the refractive index (n4) of the low-refractive-index layer 21. Note that in this case, examples of the resin used in the low-refractive-index layer 21 again include acrylic resins and epoxy resins.

Next, as an example, taking the light-emitting element 105a shown in FIG. 11 as an example, a description is given of the path of the light 23 emitted by the light-emitting layer 6a in the light-emitting element 105a and the path of external light 24 incident to the light-emitting element 105a. Note that the light 23 is monochromatic (first color) visible light.

Referring to FIG. 11, light 23a that is part of the light 23 emitted by the light-emitting layer 6a, the part having been incident to the second electrode 7 at an angle of incidence smaller than the total reflection angle (critical angle), is transmitted through the second electrode 7, the low-refractive-index layer 21, and the circular polarizer plate 22 and discharged outside the light-emitting element 105a. Light 23b that is part of the light 23 emitted by the light-emitting layer 6a, the part having been transmitted through the first electrode 4 and incident to the light absorption layer 3, is transmitted through the light absorption layer 3 and reflected off the reflective layer 2. Light 23c that is part of the light 23 emitted by the light-emitting layer 6a, the part having been incident to the second electrode 7 at an angle of incidence greater than or equal to the total reflection angle (critical angle), is totally reflected off the interface between the second electrode 7 and the low-refractive-index layer 21, transmitted through the second electrode 7, the functional layer 6, the first electrode 4, and the light absorption layer 3, and reflected off the reflective layer 2.

As described in Embodiment 1, the light absorption layer 3 has a higher transmittance to light of a maximum light-emission luminance wavelength of the visible light of a color (first color) of the light emitted at least by the light-emitting layer 6a than to at least part of visible light other than the visible light of the first color. The light 23b and the light 23c reflected off the reflective layer 2 in the present embodiment is transmitted through, the light absorption layer 3, the first electrode 4, the functional layer 6, the second electrode 7, the low-refractive-index layer 21, and the circular polarizer plate 22 and discharged outside the light-emitting element 105a. As described here, the light-emitting element 105a can reflect the light 23b and the light 23c emitted by the light-emitting layer 6a off the reflective layer 2 for external extraction. Therefore, the light-emitting element 105a enables the extraction of the light 23a through the light 23c to the outside of the light-emitting element 105a, thereby improving light-extraction efficiency.

In addition, in the present embodiment, the light absorption layer 3 again has a higher transmittance to light of a maximum light-emission luminance wavelength of the light of a particular color (first color) of the light emitted at least by the light-emitting layer 6a than to at least part of visible light other than the visible light of the first color. Therefore, the light-emitting element 105a can enhance color purity.

Meanwhile, the external light 24 is transmitted through the circular polarizer plate 22, the low-refractive-index layer 21, the second electrode 7, the functional layer 6, and the first electrode 4 and incident to the light absorption layer 3. In the present embodiment, the light absorption layer 3 can again absorb part of the external light 24 incident to the light absorption layer 3, the part being the visible light having wavelengths that encompass the wavelength range of the first color, but exclude the visible light in the wavelength range transmitted through the light absorption layer 3. Then, in so doing, the light absorption layer 3 can absorb much of the external light 24 reflected off, for example, the inclined inner wall face 13 (inclined face portion) and/or the edge of the reflective layer 2. Therefore, the light-emitting element 105a can also restrain the reflection of the external light 24 off the reflective layer 2, improving contrast both in the regular-reflection direction and in directions other than the regular-reflection direction of the external light 24. Therefore, the light-emitting element 105a can further improve ambient contrast ratio and enables extracting more of the light 23 emitted by the light-emitting layer 6a in the front direction even under external light by means of the reflective layer 2 while maintaining display quality. Therefore, the light-emitting element 105a can maintain high front-direction luminance and achieve brighter displays.

In addition, in the present embodiment, the provision of the circular polarizer plate 22 on the second electrode 7 opposite the functional layer 6 with the low-refractive-index layer 21 being interposed between the circular polarizer plate 22 and the second electrode 7 enables efficiently absorbing the reflection of the external light 24, for example, off the interface of each layer and off the reflective layer 2, the reflection not having been absorbed by the light absorption layer 3. Therefore, contrast can be further improved under external light.

Note that as shown in FIGS. 12 to 14, the path of the light 23 emitted by the light-emitting layer 6a and the path of the external light 24 incident to the light-emitting element 105a in the light-emitting element 105b through the light-emitting element 105d are the same as in the light-emitting element 105a shown in FIG. 11. Therefore, the light-emitting element 105b through the light-emitting element 105d can achieve the same effects as the light-emitting element 105a.

Note that the structure of the insulating layer 1 through the second electrode 7 may be the same as in any one of the light-emitting element 101, the light-emitting element 101′, the light-emitting element 102a, the light-emitting element 102b, the light-emitting element 103a, the light-emitting element 103b, the light-emitting element 103b′, and the light-emitting element 104. In other words, the light-emitting element 101, the light-emitting element 101′, the light-emitting element 102a, the light-emitting element 102b, the light-emitting element 103a, the light-emitting element 103b, the light-emitting element 103b′, and the light-emitting element 104 may each include the low-refractive-index layer 21 and the circular polarizer plate 22.

### Embodiment 7

The following will describe, as an example, a display device including a plurality of pixels as a light-emitting device in accordance with the present embodiment.

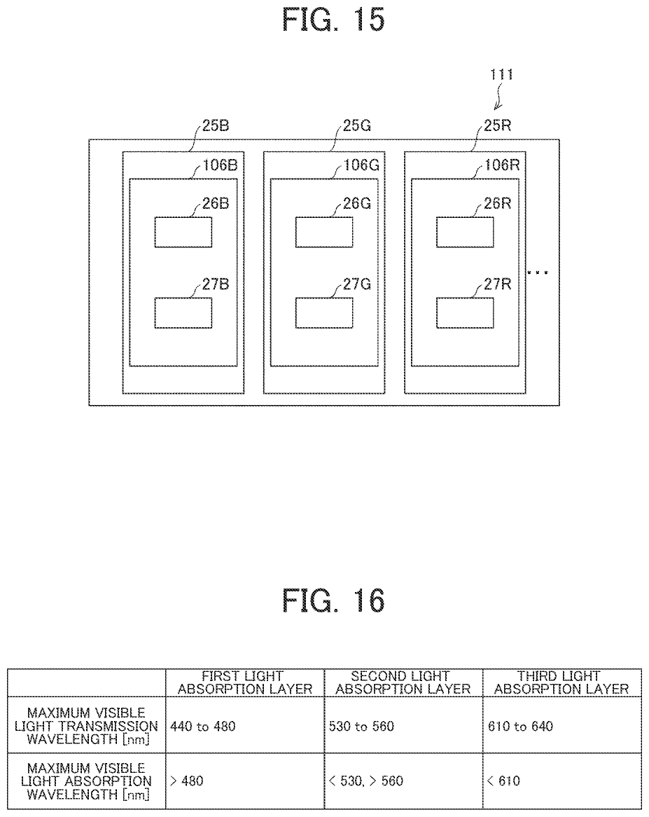

FIG. 15 is a schematic block diagram of a structure of a display device 111 in accordance with the present embodiment. Note that for convenience of illustration, FIG. 15 does not show members that are not related to the description made with reference to FIG. 15.

The display device 111 includes a first pixel 25B, a second pixel 25G, and a third pixel 25R as pixels.

The first pixel 25B is a blue pixel that emits blue light. The second pixel 25G is a green pixel that emits green light. The third pixel 25R is a red pixel that emits red light.

The first pixel 25B includes a first light-emitting element 106B. The first pixel 25B includes a first light-emitting element 106B. The second pixel 25G includes a second light-emitting element 106G. The third pixel 25R includes a third light-emitting element 106R.

The first light-emitting element 106B, the second light-emitting element 106G, and the third light-emitting element 106R may be any one of the light-emitting elements described in the foregoing embodiments. For example, each of the first light-emitting element 106B, the second light-emitting element 106G, and the third light-emitting element 106R may be the light-emitting element 101 and may be the light-emitting element 101′, the light-emitting element 102a, the light-emitting element 102b, the light-emitting element 103a, the light-emitting element 103b, the light-emitting element 103b′, the light-emitting element 104, the light-emitting element 105a, the light-emitting element 105b, the light-emitting element 105c, the light-emitting element 105d, or a light-emitting element 105e.

The first light-emitting element 106B includes a first light-emitting layer 26B as the aforementioned light-emitting layer 6a. In addition, the first light-emitting element 106B includes a first light absorption layer 27B as the aforementioned light absorption layer 3. The first light-emitting element 106B is a blue light-emitting element that emits the aforementioned blue light color as the visible light of the first color from the first light-emitting layer 26B.

The second light-emitting element 106G includes a second light-emitting layer 26G as the aforementioned light-emitting layer 6a. In addition, the second light-emitting element 106G includes a second light absorption layer 27G as the aforementioned light absorption layer 3. The second light-emitting element 106G is a green light-emitting element that emits the aforementioned green light color as the visible light of the first color from the second light-emitting layer 26G.

The third light-emitting element 106R includes a third light-emitting layer 26R as the aforementioned light-emitting layer 6a. In addition, the third light-emitting element 106R includes a third light absorption layer 27R as the aforementioned light absorption layer 3. The third light-emitting element 106R is a red light-emitting element that emits the aforementioned red light color as the visible light of the first color from the third light-emitting layer 26R.

The first light absorption layer 27B in the first light-emitting element 106B has a higher transmittance to the light of the maximum light-emission luminance wavelength of the blue light than to the visible light other than the blue light. In addition, the second light absorption layer 27G in the second light-emitting element 106G has a higher transmittance to the light of the maximum light-emission luminance wavelength of the green light than to the visible light other than the green light. The third light absorption layer 27R in the third light-emitting element 106R has a higher transmittance to the light of the maximum light-emission luminance wavelength of the red light than to the visible light other than the red light.

FIG. 16 is a diagram showing a maximum visible light transmission wavelength and a maximum visible light absorption wavelength of the first light absorption layer 27B, a maximum visible light transmission wavelength and a maximum visible light absorption wavelength of the second light absorption layer 27G, and a maximum visible light transmission wavelength and a maximum visible light absorption wavelength of the third light absorption layer 27R.

Referring to FIG. 16, the first light absorption layer 27B has a maximum visible light transmission wavelength in the wavelength range of from 440 nm to 480 nm, both inclusive, and a maximum visible light absorption wavelength in the wavelength range of above 480 nm. Therefore, the first light-emitting element 106B transmits blue light and absorbs green light and red light.

In addition, the second light absorption layer 27G has a maximum visible light transmission wavelength in the wavelength range of from 530 nm to 560 nm, both inclusive, and maximum visible light absorption wavelengths, one in the wavelength range of below 530 nm and another in the wavelength range of above 560 nm. Therefore, the second light-emitting element 106G transmits green light and absorbs blue light and red light.

In addition, the third light absorption layer 27R has a maximum visible light transmission wavelength in the wavelength range of from 610 nm to 640 nm, both inclusive, and a maximum visible light absorption wavelength in the wavelength range of below 610 nm. Therefore, the third light-emitting element 106R transmits red light and absorbs blue light and green light.

Note that in FIGS. 16, “440 to 480” refers to a range of from 440 to 480, both inclusive, “>480” refers to a range of above 480, “530 to 560” refers to a range of from 530 to 560, both inclusive, “<530” refers to a range of below 530, “>560” refers to a range of above 560, “610 to 640” refers to a range of from 610 to 640, both inclusive, and “<610” refers to a range of below 610.

As described here, in the display device 111, the maximum visible light transmission wavelength of the first light absorption layer 27B, the maximum visible light transmission wavelength of the second light absorption layer 27G, and the maximum visible light transmission wavelength of the third light absorption layer 27R are different from each other. Therefore, the display device 111, in which the maximum visible light transmission wavelength of the light absorption layer 3 differs between the first pixel 25B, the second pixel 25G, and the third pixel 25R, can absorb visible light in the wavelength band of approximately ⅔ of the total visible light wavelengths. In other words, in the display device 111, every pixel can absorb, for example, approximately ⅔ of the external light 10 or the external light 24 reflected off the reflective layer 2. Therefore, the present embodiment can provide the display device 111 that emits light with higher contrast than conventional art.

### Embodiment 8

The present embodiment will also describe, as an example, a display device including a plurality of pixels as a light-emitting device.

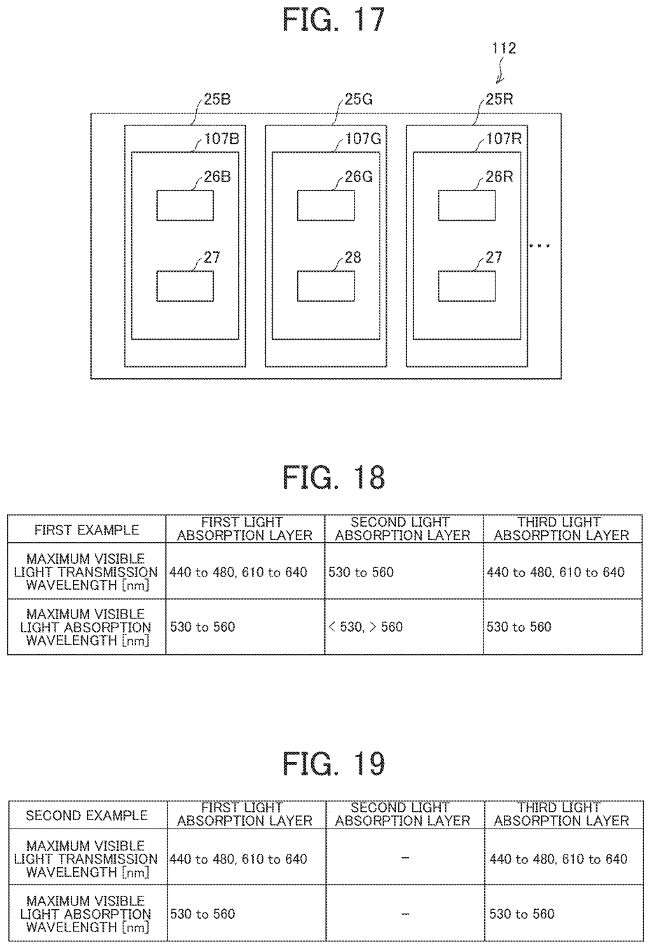

FIG. 17 is a schematic block diagram of a structure of a display device 112 in accordance with the present embodiment. Note that for convenience of illustration, FIG. 17 does not show members that are not related to the description made with reference to FIG. 17.

The display device 112 differs from the display device 111 as described below and has otherwise the same structure as the display device 111 except for the points given below.

In the display device 112, the first pixel 25B includes a first light-emitting element 107B in place of the first light-emitting element 106B. The second pixel 25G includes a second light-emitting element 107G in place of the second light-emitting element 106G. The third pixel 25R includes a third light-emitting element 107R in place of the third light-emitting element 106R.

The first light-emitting element 107B, similarly to the first light-emitting element 106B, is a blue light-emitting element that emits blue light color as the visible light of the first color from the first light-emitting layer 26B. The second light-emitting element 107G, similarly to the second light-emitting element 106G, is a green light-emitting element that emits green light color as the visible light of the first color from the second light-emitting layer 26G. The third light-emitting element 107R, similarly to the third light-emitting element 106R, is a red light-emitting element that emits red light color as the visible light of the first color from the third light-emitting layer 26R.

The first light-emitting element 107B includes, as the aforementioned light absorption layer 3, a light absorption layer 27 that serves as a first light absorption layer (i.e., a light absorption layer in the first light-emitting element) in place of the first light absorption layer 27B. The second light-emitting element 107G includes, as the aforementioned light absorption layer 3, a light absorption layer 28 that serves as a second light absorption layer (i.e., a light absorption layer in the second light-emitting element) in place of the second light absorption layer 27G. The third light-emitting element 107R includes, as the aforementioned light absorption layer 3, the light absorption layer 27 that serves as a third light absorption layer (i.e., a light absorption layer in the third light-emitting element) in place of the third light absorption layer 27R.

The light absorption layers 27 in the first light-emitting element 107B and the third light-emitting element 107R have a higher transmittance to the light of the maximum light-emission luminance wavelength of the blue light and to the light of the maximum light-emission luminance wavelength of the red light than to the visible light other than the red light and the blue light. In addition, the light absorption layer 28 in the second light-emitting element 107G has a higher transmittance to the light of the maximum light-emission luminance wavelength of the green light than to the visible light other than the green light.

FIG. 18 is a diagram showing a maximum visible light transmission wavelength and a maximum visible light absorption wavelength of the light absorption layer 27 as the first light absorption layer and the third light absorption layer and a maximum visible light transmission wavelength and a maximum visible light absorption wavelength of the light absorption layer 28 as the second light absorption layer.

Referring to FIG. 18, the light absorption layer 27 as the first light absorption layer and the third light absorption layer has maximum visible light transmission wavelengths, one in the wavelength range of from 440 nm to 480 nm, both inclusive, and another in the wavelength range of from 610 nm to 640 nm, both inclusive, and a maximum visible light absorption wavelength in the wavelength range of from 530 nm to 560 nm, both inclusive. Therefore, the first light-emitting element 107B and the third light-emitting element 107R transmit blue light and red light and absorb green light.

In addition, the light absorption layer 28 as the second light absorption layer, similarly to the second light absorption layer 27G, has a maximum visible light transmission wavelength in the wavelength range of from 530 nm to 560 nm, both inclusive, and maximum visible light absorption wavelengths, one in the wavelength range of below 530 nm and another in the wavelength range of above 560 nm. Therefore, the second light-emitting element 106G transmits green light and absorbs blue light and red light.

Note that in FIG. 18, as in a previous figure, “440 to 480” refers to a range of from 440 to 480, both inclusive, “610 to 640” refers to a range of from 610 to 640, both inclusive, and “530 to 560” refers to a range of from 530 to 560, both inclusive. In addition, “<530” refers to a range of below 530, and “>560” refers to a range of above 560.

As described here, the display device 112 includes, as the light absorption layer 3, the light absorption layer 27 for transmitting red light and blue light absorbing only green light, which is more visually recognizable, in each of the first light-emitting element 107B and the third light-emitting element 107R.

Therefore, in the display device 112, the light absorption layer 27 can be formed as the light absorption layer 3 simultaneously in the first light-emitting element 107B and in the third light-emitting element 107R, which reduces the number of times the light absorption layer 3 is subjected to patterning to, for example, 2.

In addition, in the display device 112, the first pixel 25B and the third pixel 25R can absorb visible light in the wavelength band of approximately ⅓ of the total visible light wavelengths, and the second pixel 25G can absorbs visible light in the wavelength band of approximately ⅔ of the total visible light wavelengths. In other words, the first pixel 25B and the third pixel 25R absorb, for example, approximately ⅓ of the external light 10 or the external light 24 reflected off the reflective layer 2, whereas the second pixel 25G absorbs, for example, approximately 4/9 of the external light 10 or the external light 24 reflected off the reflective layer 2 (specifically, red light: 1/9, green light: 2/9, and blue light: 1/9). Therefore, the present embodiment can provide the display device 112 that emits light with higher contrast than conventional art.

### Variation Example 1

FIG. 19 is a diagram showing a maximum visible light transmission wavelength and a maximum visible light absorption wavelength of the light absorption layer 27 as the first light absorption layer and the third light absorption layer and a maximum visible light transmission wavelength and a maximum visible light absorption wavelength of the light absorption layer 28 as the second light absorption layer, in the display device 112 in accordance with the present variation example.

Referring to FIG. 19, for example, the light absorption layer 28 as the second light absorption layer may absorb negligibly little light.

In this case, the second pixel 25G can practically not absorb the external light 10 or the external light 24 reflected off the reflective layer 2, but can absorb, for example, approximately 2/9 of the external light 10 or the external light 24 reflected off the reflective layer 2.

### Variation Example 2

Embodiments 7 to 8 above have described, as an example, the light-emitting device in accordance with the present disclosure as being a display device. However, the light-emitting device in accordance with the present disclosure is not limited to this example and may be, for example, a lighting device or a light-emitting element.

### General Description

The present disclosure, in aspect 1 thereof, is directed to a light-emitting element including: a reflective layer; a light absorption layer; a first electrode that is transparent to visible light; a functional layer including at least a light-emitting layer configured to emit visible light of a first color; and a second electrode that is transparent to visible light, all of which are provided in a stated order, wherein the light absorption layer transmits at least part of the visible light of the first color and absorbs at least part of visible light other than the visible light of the first color, is disposed adjacent to both the reflective layer and the first electrode, and covers the entire reflective layer in a light-emitting region of the light-emitting element.

This aspect enables reflecting the visible light of the first color emitted by the light-emitting layer off the reflective layer for external extraction, thereby improving light-extraction efficiency. Meanwhile, the aspect enables the light absorption layer to absorb at least part of the external light reflected off the reflective layer, thereby restraining reflection of the external light. Therefore, the aspect can provide a light-emitting element that can improve contrast in the regular-reflection direction and that can maintain display quality even under external light.

In aspect 2 of the present disclosure, the light-emitting element of aspect 1 is configured such that the visible light of the first color has a light-emission spectrum with a full width at half maximum of less than or equal to 50 nm.

This aspect reduces the absorption by the light absorption layer, which enables brighter displays. If the wavelength range of the visible light region, which is from 400 nm to 700 nm, is broadly divided into red, green, and blue, the wavelength range for each color has a width of approximately 100 nm. If the full width at half maximum of the light emitted by the light-emitting layer is reduced to or below half the wavelength for each color, it becomes easier to strike a balance between the transmission of the light emitted by the light-emitting layer and the absorption of external light in the light absorption layer.

In aspect 3 of the present disclosure, the light-emitting element of aspect 1 or 2 is configured so as to further include an edge cover on the first electrode opposite the light absorption layer, the edge cover covering an edge of the first electrode, wherein the edge cover is absorptive to visible light, and the edge cover directly or indirectly covers a portion of the reflective layer that is out of the light-emitting region.

This aspect enables restraining reflection of external light in a portion of the reflective layer that is out of the light-emitting region.

In aspect 4 of the present disclosure, the light-emitting element of any one of aspects 1 to 3 is configured so as to further include a low-refractive-index layer adjacent to a face of the second electrode opposite the functional layer, the low-refractive-index layer having a lower refractive index than an average refractive index of layers from the first electrode through the second electrode in the light-emitting region, wherein the average refractive index of the layers from the first electrode through the second electrode in the light-emitting region differs from the refractive index of the low-refractive-index layer by a larger refractive index difference than the average refractive index of the layers from the first electrode through the second electrode in the light-emitting region differs from a refractive index of the light absorption layer.

In this aspect, owing to the refractive index difference, part of the light emitted by the light-emitting layer, the part having been incident to the low-refractive-index layer in an oblique direction at an angle (angle of incidence) greater than or equal to the total reflection angle (critical angle), can be totally reflected, guided to the light absorption layer, and reflected off the reflective layer for external extraction. Therefore, the external light-extraction efficiency can be improved. In addition, the interface reflectance at angles less than or equal to the total reflection angle is lower at the interface between the functional layer and the light absorption layer than at the interface between the functional layer and the low-refractive-index, thereby enabling guiding the light emitted in the functional layer preferentially to the light absorption layer.

In aspect 5 of the present disclosure, the light-emitting element of aspect 4 is configured such that the low-refractive-index layer is made of a resin having a refractive index of from 1.3 to 1.6, both inclusive.

Broadly available low-refractive-index resins have a refractive index of approximately 1.3. If the refractive index is greater than or equal to 1.6, the average refractive index of the layers from the first electrode through the second electrode needs to be greater than or equal to 1.6, which limits structural options of the functional layer.

In aspect 6 of the present disclosure, the light-emitting element of aspect 4 is configured such that the low-refractive-index layer is made of a hollow-bead-containing resin containing a plurality of hollow beads.

In aspect 7 of the present disclosure, the light-emitting element of aspect 4 is configured such that the low-refractive-index layer is either hollow or a gas layer.

In aspect 8 of the present disclosure, the light-emitting element of any one of aspects 4 to 7 is configured so as to further include a circular polarizer plate on the second electrode opposite the functional layer with the low-refractive-index layer being interposed between the circular polarizer plate and the second electrode.

This configuration enables efficiently absorbing the reflection of the external light, for example, off the interface of each layer and off the reflective layer, the reflection not having been absorbed by the light absorption layer. Therefore, contrast can be further improved under external light.

In aspect 9 of the present disclosure, the light-emitting element of any one of aspects 1 to 8 is configured such that the reflective layer has at least one depression with an inclined inner wall face in the light-emitting region.

In this aspect, the provision of the reflective layer having such a structure enables prevention of waveguide loss and improvement of the light-extraction efficiency of the light-emitting element in the front direction. In addition, in the absence of the light absorption layer, if the reflective layer with the aforementioned structure is provided, the external light is scatteringly reflected off, for example, the inclined inner wall face (inclined face portion) and/or the edge of the reflective layer, thereby allowing the external light to reduce contrast both in the regular-reflection direction of the external light and in directions other than the regular-reflection direction. However, the aspect enables the light absorption layer to absorb the external light reflected off, for example, the inclined inner wall face (inclined face portion) and/or the edge of the reflective layer, thereby improving contrast also in directions other than the regular-reflection direction of the light-emitting element. Therefore, the aspect enables further improving ambient contrast ratio and enables extracting more of the light emitted by the light-emitting layer in the front direction even under external light by means of the reflective layer while maintaining display quality. Therefore, the aspect can maintain high front-direction luminance of the light-emitting element and enable brighter displays.

In aspect 10 of the present disclosure, the light-emitting element of aspect 9 is configured such that the light absorption layer is thicker in a portion of the light absorption layer that covers the depression in the reflective layer in the light-emitting region than in a portion of the light absorption layer that covers a part of the reflective layer other than the depression in the light-emitting region.

This aspect more reliably enables the light absorption layer to absorb the external light reflected off, for example, the inclined inner wall face (inclined face portion) and/or the edge of the depression in the reflective layer and also enables increasing the thickness of the light absorption layer in the depression, which renders the light absorption layer less likely to come off.

In aspect 11 of the present disclosure, the light-emitting element of aspect 9 or 10 is configured so as to further include a first insulating layer on the reflective layer opposite the light absorption layer, the first insulating layer having at least one depression with an inclined inner wall face in the light-emitting region, wherein the reflective layer is disposed along at least a part of a surface of the first insulating layer at least in the light-emitting region so as to cover at least a part of the inner wall face of the depression in the first insulating layer.

In this aspect, the provision of the reflective layer along at least a part of the surface of the first insulating layer on the first insulating layer having a depression having an inclined inner wall face facilitates the formation of the reflective layer having the depression with the inclined inner wall face.

In aspect 12 of the present disclosure, the light-emitting element of aspect 11 is configured such that the first insulating layer includes a plurality of the depressions in the light-emitting region, and the reflective layer covers at least the entire inner wall faces of the plurality of the depressions in the first insulating layer in the light-emitting region.

This aspect enables providing a light-emitting element having such a plurality of inclined reflective surfaces as to further improve light-extraction efficiency in the front direction.

In aspect 13 of the present disclosure, the light-emitting element of aspect 11 is configured such that the reflective layer covers a part of the inner wall face of the depression in the first insulating layer in the light-emitting region.

According to this configuration, the reflective layer having a depression with an inclined inner wall face covering a part of the inner wall face of the depression in the first insulating layer in the light-emitting region reduces the area of the face off which the external light is reflected, thereby improving contrast under external light.

In aspect 14 of the present disclosure, the light-emitting element of aspect 13 is configured such that the first electrode is provided only in a part overlapping the reflective layer in a plan view.

In this aspect, since the light-extraction efficiency is low where no reflective layer is provided, no first electrode is provided in the portions where the light-extraction efficiency is low, which restrains material expenses to deliver an inexpensive structure and also enables improving the light-extraction efficiency in portions where the first electrode is provided.

In aspect 15 of the present disclosure, the light-emitting element of aspect 12 or 13 is configured so as to further include a second insulating layer between the first electrode and the second electrode in a part not overlapping the depression in a plan view.

In this aspect, the provision of the second insulating layer between the first electrode and the second electrode in a part not overlapping the depression in a plan view restricts the current conduction region only to those regions where the light-extraction efficiency is high, which restrains power consumption.

In aspect 16 of the present disclosure, the light-emitting element of aspect 13 or 14 is configured such that the light absorption layer has a higher refractive index than does the first insulating layer.

This aspect enables totally reflecting the light having been incident to the low-refractive-index layer in an oblique direction at an angle (angle of incidence) greater than or equal to the total reflection angle (critical angle) off the first insulating layer via the light absorption layer, thereby improving the external light-extraction efficiency.

In aspect 17 of the present disclosure, the light-emitting element of aspect 16 is configured such that an average refractive index of layers from the first electrode through the second electrode in the light-emitting region is higher than a refractive index of the first insulating layer.

This aspect facilitates the transmission through the functional layer of the light having been incident to the low-refractive-index layer in an oblique direction at an angle (angle of incidence) greater than or equal to the total reflection angle (critical angle) via the light absorption layer for external extraction, thereby further improving the external light-extraction efficiency.

In aspect 18 of the present disclosure, the light-emitting element of any one of aspects 11 to 17 is configured such that the first insulating layer is absorptive to visible light.

This aspect enables even the first insulating layer to restrain the reflection of external light, thereby further improving contrast under external light.

In aspect 19 of the present disclosure, the light-emitting element of any one of aspects 11 to 18 is configured such that the depression in the first insulating layer has at least a linearly formed portion.

This aspect facilitates application of materials constituting the light absorption layer, thereby enabling reliably covering the edge of reflective layer. In addition, the light absorption layer having a contiguously formed increased-thickness portion covering the depression in the first insulating layer on which the reflective layer is provided renders the light absorption layer less likely to come off.

In aspect 20 of the present disclosure, the light-emitting element of any one of aspects 1 to 19 is configured such that the light absorption layer has a higher transmittance to light of a maximum light-emission luminance wavelength of the visible light of the first color than to the at least part of visible light other than the visible light of the first color.

In this aspect, the maximum light-emission luminance wavelength of at least the visible light of the first color is the maximum visible light transmission wavelength of the light absorption layer. In addition, this aspect enables the light absorption layer to absorb much of the external light reflected off the reflective layer, thereby restraining the reflection of external light.

In aspect 21 of the present disclosure, the light-emitting element of any one of aspects 1 to 20 is configured such that the light-emitting layer contains quantum dots configured to emit the visible light of the first color.

This aspect enables the light-emitting element to improve contrast in the regular-reflection direction, thereby enabling providing a quantum-dot light-emitting diode capable of maintaining display quality even under external light.

The present disclosure, in aspect 22 thereof, is directed to a light-emitting device including a plurality of the light-emitting elements of any one of aspects 1 to 21.

This aspect can provide a light-emitting device capable of improving contrast in the regular-reflection direction and thereby maintaining display quality even under external light.

In aspect 23 of the present disclosure, the light-emitting device of aspect 22 is configured such that the plurality of the light-emitting elements include a red light-emitting element configured to emit red light as the visible light of the first color, a green light-emitting element configured to emit green light as the visible light of the first color, and a blue light-emitting element configured to emit blue light as the visible light of the first color, and the light absorption layer in the red light-emitting element and the light absorption layer in the blue light-emitting element have a higher transmittance to light of a maximum light-emission luminance wavelength of the red light and to light of a maximum light-emission luminance wavelength of the blue light than to visible light other than the red light and the blue light.

This aspect enables simultaneously forming the light absorption layer in the red light-emitting element and the light absorption layer in the blue light-emitting element, which reduces the number of times the light absorption layer is subjected to patterning to, for example, 2. This aspect also enables the red light-emitting element and the blue light-emitting element to absorb, for example, approximately ⅓ of external light and enables the green light-emitting element to absorb, for example, approximately ⅔ of external light.

In aspect 24 of the present disclosure, the light-emitting device of aspect 22 is configured such that the plurality of the light-emitting elements include a red light-emitting element configured to emit red light as the visible light of the first color, a green light-emitting element configured to emit green light as the visible light of the first color, and a blue light-emitting element configured to emit blue light as the visible light of the first color, the light absorption layer in the red light-emitting element has a higher transmittance to light of a maximum light-emission luminance wavelength of the red light than to visible light other than the red light, the light absorption layer in the green light-emitting element has a higher transmittance to light of a maximum light-emission luminance wavelength of the green light than to visible light other than the green light, and the light absorption layer in the blue light-emitting element has a higher transmittance to light of a maximum light-emission luminance wavelength of the blue light than to visible light other than the blue light.

This aspect enables each of the blue light-emitting element, the green light-emitting element, and the red light-emitting element to absorb, for example, approximately ⅔ of the external light across the whole wavelength range.

The present disclosure is not limited to the description of the embodiments above and may be altered within the scope of the claims. Embodiments based on a proper combination of technical means disclosed in different embodiments and those based on modifications of the foregoing embodiments are encompassed in the technical scope of the present disclosure. Furthermore, new technological features can be created by combining different technical means disclosed in the embodiments.

### REFERENCE SIGNS LIST

1 Insulating layer (first insulating layer)
2 Reflective layer
3, 27, 28 Light absorption layer
4 First electrode
5 Edge cover
6 Functional layer
6A Light-emitting layer
6B Insulating layer (Second insulating layer)
7 Second electrode
8,8a, 8b, 23, 23a, 23b, 23c Light
9 Light-emitting region
10, 24 External light
11R, 11G, 11B, 12R, 12G, 12B Light-emission spectrum
11BF, 12RF Full width at half maximum
13, 15 Inner wall face
14, 16 Depression
17 Top portion
18a, 18b, 18c, 18d, 18e Insulating layer structure
19 Linear portion
20 Substrate
21 Low-refractive-index layer
22 Circular polarizer plate
25B First pixel
25G Second pixel
25R Third pixel
26B First light-emitting layer
26G Second light-emitting layer
26R Third light-emitting layer
27B First light absorption layer
27G Second light absorption layer
27R Third light absorption layer
101, 101′, 102a, 102b, 103a, 103b, 103b′, 104, 105 Light-emitting element
106B, 107B First light-emitting element
106G, 107G Second light-emitting element
106R, 107R Third light-emitting element
111, 112 Display device (Light-emitting device)
121 Resin
122 Hollow bead
124 Gas layer
ta, tb Thickness

1. A light-emitting element comprising:
a reflective layer;
a light absorption layer;
a first electrode that is transparent to visible light;
a functional layer including at least a light-emitting layer configured to emit visible light of a first color; and
a second electrode that is transparent to visible light, all of which are provided in a stated order, wherein
the light absorption layer
transmits at least part of the visible light of the first color and absorbs at least part of visible light other than the visible light of the first color,
is disposed adjacent to both the reflective layer and the first electrode, and
covers the entire reflective layer in a light-emitting region of the light-emitting element.

2. The light-emitting element according to claim 1, wherein the visible light of the first color has a light-emission spectrum with a full width at half maximum of less than or equal to 50 nm.

3. The light-emitting element according to claim 1, further comprising an edge cover on the first electrode opposite the light absorption layer, the edge cover covering an edge of the first electrode, wherein
the edge cover is absorptive to visible light, and
the edge cover directly or indirectly covers a portion of the reflective layer that is out of the light-emitting region.

4. The light-emitting element according to claim 1, further comprising a low-refractive-index layer adjacent to a face of the second electrode opposite the functional layer, the low-refractive-index layer having a lower refractive index than an average refractive index of layers from the first electrode through the second electrode in the light-emitting region, wherein
the average refractive index of the layers from the first electrode through the second electrode in the light-emitting region differs from the refractive index of the low-refractive-index layer by a larger refractive index difference than the average refractive index of the layers from the first electrode through the second electrode in the light-emitting region differs from a refractive index of the light absorption layer.

5. The light-emitting element according to claim 4, wherein the low-refractive-index layer is made of a resin having a refractive index of from 1.3 to 1.6, both inclusive.

6. The light-emitting element according to claim 4, wherein the low-refractive-index layer is made of a hollow-bead-containing resin containing a plurality of hollow beads.

7. The light-emitting element according to claim 4, wherein the low-refractive-index layer is either hollow or a gas layer.

8. The light-emitting element according to claim 4, further comprising a circular polarizer plate on the second electrode opposite the functional layer with the low-refractive-index layer being interposed between the circular polarizer plate and the second electrode.

9. The light-emitting element according to claim 1, wherein the reflective layer has at least one depression with an inclined inner wall face in the light-emitting region.

10. The light-emitting element according to claim 9, wherein the light absorption layer is thicker in a portion of the light absorption layer that covers the depression in the reflective layer in the light-emitting region than in a portion of the light absorption layer that covers a part of the reflective layer other than the depression in the light-emitting region.

11. The light-emitting element according to claim 9, further comprising a first insulating layer on the reflective layer opposite the light absorption layer, the first insulating layer having at least one depression with an inclined inner wall face in the light-emitting region, wherein
the reflective layer is disposed along at least a part of a surface of the first insulating layer at least in the light-emitting region so as to cover at least a part of the inner wall face of the depression in the first insulating layer.

12. The light-emitting element according to claim 11, wherein
the first insulating layer includes a plurality of the depressions in the light-emitting region, and
the reflective layer covers at least the entire inner wall faces of the plurality of the depressions in the first insulating layer in the light-emitting region.

13. The light-emitting element according to claim 11, wherein the reflective layer covers a part of the inner wall face of the depression in the first insulating layer in the light-emitting region.

14. (canceled)

15. (canceled)

16. (canceled)

17. (canceled)

18. The light-emitting element according to claim 11, wherein the first insulating layer is absorptive to visible light.

19. The light-emitting element according to claim 11, wherein the depression in the first insulating layer has at least a linearly formed portion.

20. The light-emitting element according to claim 1, wherein the light absorption layer has a higher transmittance to light of a maximum light-emission luminance wavelength of the visible light of the first color than to the at least part of visible light other than the visible light of the first color.

21. The light-emitting element according to claim 1, wherein the light-emitting layer contains quantum dots configured to emit the visible light of the first color.

22. A light-emitting device comprising a plurality of the light-emitting elements according to claim 1.

23. The light-emitting device according to claim 22, wherein
the plurality of the light-emitting elements include a red light-emitting element configured to emit red light as the visible light of the first color, a green light-emitting element configured to emit green light as the visible light of the first color, and a blue light-emitting element configured to emit blue light as the visible light of the first color, and
the light absorption layer in the red light-emitting element and the light absorption layer in the blue light-emitting element have a higher transmittance to light of a maximum light-emission luminance wavelength of the red light and to light of a maximum light-emission luminance wavelength of the blue light than to visible light other than the red light and the blue light.

24. The light-emitting device according to claim 22, wherein
the plurality of the light-emitting elements include a red light-emitting element configured to emit red light as the visible light of the first color, a green light-emitting element configured to emit green light as the visible light of the first color, and a blue light-emitting element configured to emit blue light as the visible light of the first color,
the light absorption layer in the red light-emitting element has a higher transmittance to light of a maximum light-emission luminance wavelength of the red light than to visible light other than the red light,
the light absorption layer in the green light-emitting element has a higher transmittance to light of a maximum light-emission luminance wavelength of the green light than to visible light other than the green light, and
the light absorption layer in the blue light-emitting element has a higher transmittance to light of a maximum light-emission luminance wavelength of the blue light than to visible light other than the blue light.
